(19) United States
(12) Patent Application Publication
(10) Pub. No.: US 2026/0006989 A1
(43) Pub. Date: Jan. 1, 2026

(54) DISPLAY DEVICE AND METHOD FOR FABRICATING THE SAME

(71) Applicant: Samsung Display Co., Ltd., Yongin-Si (KR)

(72) Inventors: Beom Soo PARK, Yongin-si (KR); Seong Jun LEE, Yongin-si (KR); Jae Ik LIM, Yongin-si (KR)

(21) Appl. No.: 18/959,665

(22) Filed: Nov. 26, 2024

(30) Foreign Application Priority Data
Jun. 26, 2024 (KR) 10-2024-0083756
Jul. 26, 2024 (KR) 10-2024-0099602

(51) Int. Cl. H10K 59/121; H10K 59/12

(52) U.S. Cl. CPC H10K 59/1213; H10K 59/1201; H10K 59/1216

(57) ABSTRACT

There is provided a display device comprises a substrate; a circuit layer; and an element layer. The circuit layer includes a first semiconductor layer; a first gate insulating layer; a first gate conductive layer; a second gate insulating layer; a second gate conductive layer; a first interlayer insulating layer; a second semiconductor layer; a third gate insulating layer; a third gate conductive layer; a second interlayer insulating layer; a first source-drain conductive layer disposed with a first thickness; and contact holes for electrical contact between one of the first semiconductor layer, the first gate conductive layer, and the second gate conductive layer and the first source-drain conductive layer. A portion of the first source-drain conductive layer adjacent to the vicinity of each of the contact holes is disposed with a second thickness smaller than the first thickness.

### CROSS-REFERENCE TO RELATED APPLICATION

This application claims priority to Korean Patent Application No. 10-2024-0083756 filed on Jun. 26, 2024, in the Korean Intellectual Property Office and Korean Patent Application No. 10-2024-0099602 filed on Jul. 26, 2024, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device and a method for fabricating the same.

### 2. Description of the Related Art

As an information society develops, the demand for a display device for displaying an image is increasing in various forms. For example, the display device has been applied to various electronic devices such as smartphones, digital cameras, laptop computers, navigation devices, and smart televisions.

The display device may be a flat panel display device such as a liquid crystal display device, a field emission display device, or a light emitting display device. Here, the light emitting display device may include an organic light emitting display device including an organic light emitting element, an inorganic light emitting display device including an inorganic light emitting element such as an inorganic semiconductor, and a micro or nano light emitting display device including a micro or nano light emitting element.

The organic light emitting display device displays an image using light emitting elements each including a light emitting layer made of an organic light emitting material. As such, as the organic light emitting display device implements image display using self-light emitting elements, the organic light emitting display device may have relatively superior performance in terms of power consumption, response speed, emission efficiency, luminance, and wide viewing angle compared to other display devices.

A display surface of the display device from which light is emitted may include a display area where an image is displayed and a non-display area surrounding the display area. Light emitting areas that emit light with respective luminance and color may be arranged in the display area.

### SUMMARY

The display device may include a stacked structure of inorganic insulating layers, each including an inorganic insulating material.

However, during the fabricating or use of the display device, an external shock may be temporarily applied to the display device due to accidents such as collision with another object or falling of the device. In this case, since the inorganic insulating layers have relatively low elasticity, cracks in the inorganic insulating layers may relatively easily occur when a shock exceeding a critical value is concentrated. In addition, as the cracks in the inorganic insulating layers expand, short circuit or open circuit defects may occur.

Aspects of the present disclosure provide a display device and a method for fabricating the same, which may reduce crack defects in an inorganic insulating layer.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device comprises a substrate including a display area in which light emitting areas are arranged; a circuit layer disposed on the substrate, the circuit layer including light emitting pixel drivers each of which includes a first semiconductive layer disposed on the substrate and a first source-drain conductive layer connected to the first semiconductive layer; and an element layer disposed on the circuit layer and connected to the circuit layer. The first source-drain conductive layer may include includes a first portion disposed adjacent to a first contact hole and a second portion connected to the first portion and the first portion may have a first thickness and the second portion may has a second thickness thicker than the first thickness.

The each of the light emitting pixel drivers may further include a first gate insulating layer covering the first semiconductor layer, a first gate conductive layer disposed on the first gate insulating layer, a second gate insulating layer covering the first gate conductive layer, a second gate conductive layer disposed on the second gate insulating layer, a first interlayer insulating layer covering the second gate conductive layer, a second semiconductor layer disposed on the first interlayer insulating layer, a third gate insulating layer covering the second semiconductor layer, a third gate conductive layer disposed on the third gate insulating layer and a second interlayer insulating layer covering the third gate conductive layer. The each of the light emitting pixel drivers may include contact holes which includes the first contact hole, one of the first semiconductor layer. The first gate conductive layer and the second gate conductive layer may be connected to the first source-drain conductive layer through a corresponding contact hole. The first source-drain conductive layer may be disposed on the second interlayer insulating layer. The element layer includes light emitting elements disposed in the light emitting areas and is connected to the light emitting pixel drivers. The each of the light emitting pixel drivers includes a first transistor electrically connected between a first node and a second node; and a second transistor electrically connected between a data line transmitting a data signal and the first node. The first node is electrically connected to a first electrode of the first transistor. The second node is electrically connected to a second electrode of the first transistor. Each of the first transistor and the second transistor includes a channel portion, a first electrode portion, and a second electrode portion disposed in the first semiconductor layer. In each of the first transistor and the second transistor, the first electrode portion is connected to one side of the channel portion, and the second electrode portion is connected to the other side of the channel portion.

The each of the light emitting pixel drivers further includes a data connection electrode disposed in the first source-drain conductive layer. The data line is disposed in the second source-drain conductive layer and is electrically connected to the data connection electrode through a data contact hole formed in the second planarization layer. The contact holes include a data auxiliary contact hole through which the data connection electrode and the first electrode portion of the second transistor are connected. A portion of the data connection electrode disposed between at least one side of the data auxiliary contact hole and an edge of the data connection electrode has the second thickness.

The each of the light emitting pixel drivers further includes a third transistor electrically connected between the second node and the third node; and a fourth transistor electrically connected between a first initialization voltage line transmitting a first initialization voltage and the third node. Each of the third transistor and the fourth transistor includes a channel portion, a first electrode portion, and a second electrode portion disposed in the second semiconductor layer. In each of the third transistor and the fourth transistor, the first electrode portion is connected to one side of the channel portion, and the second electrode portion is connected to the other side of the channel portion. The each of the light emitting pixel drivers further includes a gate connection electrode disposed in the first source-drain conductive layer. A gate electrode of the first transistor is disposed in the first gate conductive layer. The second electrode portion of the third transistor and the second electrode portion of the fourth transistor are connected to each other and are electrically connected to the gate connection electrode through a first gate contact hole formed in the second interlayer insulating layer and the third gate insulating layer. The gate connection electrode and the gate electrode of the first transistor are connected to each other through a second gate contact hole. A portion of the gate contact electrode between at least one side of the second gate contact hole and an edge of the gate connection electrode has the second thickness.

The circuit layer further includes a first initialization contact electrode disposed in the first source-drain conductive layer. The first initialization voltage line is disposed in the first gate conductive layer. The first electrode portion of the fourth transistor is electrically connected to the first initialization connection electrode through a first initialization contact hole formed in the second interlayer insulating layer and the third gate insulating layer. The contact holes further include a second initialization contact hole through which the first initialization connection electrode and the first initialization voltage line are connected. A portion of the first initialization connection electrode between at least one side of the second initialization contact hole and an edge of the first initialization connection electrode has the second thickness.

The each of the light emitting pixel drivers further includes a pixel capacitor electrically connected between a first power line transmitting a first power and a third node; a fifth transistor electrically connected between the first power line and the first node; a sixth transistor electrically connected between the second node and a fourth node; a seventh transistor electrically connected between a second initialization voltage line transmitting a second initialization voltage and the fourth node; and an eighth transistor electrically connected between a bias voltage line transmitting a bias voltage and the first node. Each of the fifth transistor, the sixth transistor, the seventh transistor, and the eighth transistor includes a channel portion, a first electrode portion, and a second electrode portion disposed in the first semiconductor layer. In each of the fifth transistor, the sixth transistor, the seventh transistor, and the eighth transistor, the first electrode portion is connected to one side of the channel portion and the second electrode portion is connected to the other side of the channel portion. The third node is electrically connected to the gate electrode of the first transistor. The fourth node is electrically connected to a light emitting element. The circuit layer further includes a capacitor electrode disposed in the second gate conductive layer and overlapping the gate electrode of the first transistor; and a power connection electrode disposed in the first source-drain conductive layer. The first power line is disposed in the second source-drain conductive layer and is electrically connected to the power connection electrode through a first power contact hole formed in the first planarization layer. The contact holes further include a second power contact hole through which the capacitor electrode and the power connection electrode are connected; and a third power contact hole electrically connecting the first electrode portion of the fifth transistor and the power connection electrode. A portion of the power connection electrode between at least one side of the second power contact hole and an edge of the power connection electrode, and another portion between at least one side of the third power contact hole and the edge of the power connection electrode are disposed with the second thickness.

The circuit layer further includes a first node contact electrode disposed in the first source-drain conductive layer. The contact holes further include a first node contact hole electrically connecting the second electrode portion of the fifth transistor and the first node connection electrode. A second node contact hole electrically connecting the second electrode portion of the eighth transistor and the first node connection electrode. A portion of the first node connection electrode between at least one side of the first node contact hole and an edge of the first node connection electrode, and another portion between at least one side of the second node contact hole and the edge of the first node connection electrode are disposed with the second thickness.

The circuit layer further includes a second node connection electrode disposed in the first source-drain conductive layer. The first electrode portion of the third transistor is electrically connected to the second node connection electrode through a third node contact hole formed in the second interlayer insulating layer and the third gate insulating layer. The contact holes further include a fourth node contact hole through which the second node connection electrode and the second electrode portion of the first transistor are connected. A portion of the second node connection electrode between at least one side of the fourth node contact hole and an edge of the second node connection electrode has the second thickness.

The circuit layer further includes a bias connection electrode disposed in the first source-drain conductive layer. The bias voltage line is disposed in the third gate conductive layer and is electrically connected to the bias connection electrode through a first bias contact hole formed in the second interlayer insulating layer. The contact holes further include a second bias contact hole through which the first electrode portion of the eighth transistor and the bias connection electrode are connected. A portion of the bias connection electrode between at least one side of the second bias contact hole and an edge of the bias connection electrode has the second thickness.

The circuit layer further includes a first anode connection electrode disposed in the first source-drain conductive layer; and a second anode connection electrode disposed in the second source-drain conductive layer. The second electrode portion of the sixth transistor and the second electrode portion of the seventh transistor are connected to each other and electrically connected to the first anode connection electrode through a first anode contact hole, which is one of the contact holes. The second anode connection electrode is electrically connected to the first anode connection electrode through a second anode contact hole formed in the first planarization layer. The one light emitting element is electrically connected to the second anode connection electrode through a third anode contact hole formed in the second planarization layer. A portion of the first anode connection electrode between at least one side of the first anode contact hole and an edge of the first anode connection electrode has the second thickness.

The circuit layer further includes a second initialization connection electrode disposed in the first source-drain conductive layer. The second initialization voltage line is disposed in the third gate conductive layer and is electrically connected to the second initialization connection electrode through a third initialization contact hole formed in the second interlayer insulating layer. The contact holes further include a fourth initialization contact hole through which the second initialization connection electrode and the first electrode portion of the seventh transistor are connected. A portion of the second initialization connection electrode between at least one side of the fourth initialization contact hole and an edge of the second initialization connection electrode has the second thickness.

According to an aspect of the present disclosure, there is provided an electronic device comprising a display device as a display screen. The display device comprises a substrate including a display area in which light emitting areas are arranged; a circuit layer disposed on the substrate, the circuit layer including light emitting pixel drivers each of which includes a first semiconductive layer disposed on the substrate, a first source-drain conductive layer connected to the first semiconductive layer through a first contact hole disposed in an insulating layer, and an additional buffer layer disposed between the first source-drain conductive layer and the insulating layer disposed adjacent to the first contact hole; and an element layer disposed on the circuit layer and connected to the circuit layer. The each of the light emitting pixel drivers includes contact holes which include the first contact hole. One of the first semiconductor layer, the first gate conductive layer and the second gate conductive layer, and the first source-drain conductive layer are connected to the first source-drain conductive layer through a corresponding contact hole.

The each of the light emitting pixel drives further includes a first gate insulating layer covering the first semiconductor layer, a first gate conductive layer disposed on the first gate insulating layer, a second gate insulating layer covering the first gate conductive layer, a second gate conductive layer disposed on the second gate insulating layer, a first interlayer insulating layer covering the second gate conductive layer, a second semiconductor layer disposed on the first interlayer insulating layer, a third gate insulating layer covering the second semiconductor layer, a third gate conductive layer disposed on the third gate insulating layer, a second interlayer insulating layer covering the third gate conductive layer. The element layer includes light emitting elements disposed in the light emitting areas. The each of the light emitting pixel drivers includes a first transistor electrically connected between a first node and a second node; a pixel capacitor electrically connected between a first power line transmitting a first power and a third node; a second transistor electrically connected between a data line transmitting a data signal and the first node; a third transistor electrically connected between the second node and the third node; a fourth transistor electrically connected between a first initialization voltage line transmitting a first initialization voltage and the third node; a fifth transistor electrically connected between the first power line and the first node; a sixth transistor electrically connected between the second node and a fourth node; a seventh transistor electrically connected between a second initialization voltage line transmitting a second initialization voltage and the fourth node; and an eighth transistor electrically connected between a bias voltage line transmitting a bias voltage and the first node. The first node is electrically connected to a first electrode of the first transistor. The second node is electrically connected to a second electrode of the first transistor. The third node is electrically connected to a gate electrode of the first transistor. The fourth node is electrically connected to the one light emitting element. Each of the first transistor, the second transistor, the fifth transistor, the sixth transistor, the seventh transistor, and the eighth transistor includes a channel portion, a first electrode portion, and a second electrode portion disposed in the first semiconductor layer. Each of the third transistor and the fourth transistor includes a channel portion, a first electrode portion, and a second electrode portion disposed in the second semiconductor layer. In each of the first transistor, the second transistor, the third transistor, the fourth transistor, the fifth transistor, the sixth transistor, the seventh transistor and the eighth transistor, the first electrode portion is connected to one side of the channel portion, and the second electrode portion is connected to the other side of the channel portion.

The each of the light emitting pixel drivers further includes a data contact electrode disposed in the first source-drain conductive layer. The data line is disposed in the second source-drain conductive layer and is electrically connected to the data connection electrode through a data contact hole formed in the second planarization layer. The contact holes include a data auxiliary contact hole through which the data connection electrode and the first electrode portion of the second transistor are connected. A portion of the data contact electrode adjacent to the data auxiliary contact hole overlaps the additional buffer layer.

The circuit layer further includes a gate connection electrode disposed in the first source-drain conductive layer. The gate electrode of the first transistor is disposed in the first gate conductive layer. The second electrode portion of the third transistor and the second electrode portion of the fourth transistor are connected to each other and are electrically connected to the gate connected electrode through a first gate contact hole formed in the second interlayer insulating layer and the third gate insulating layer. The contact holes include a second gate contact hole through which the gate contact electrode and the gate electrode of the first transistor are connected. A portion of the data connection electrode adjacent to the second gate contact hole overlaps the additional buffer layer.

The circuit layer further includes a first anode contact electrode disposed in the first source-drain conductive layer; and a second anode contact electrode disposed in the second source-drain conductive layer. The second electrode portion of the sixth transistor and the second electrode portion of the seventh transistor are connected to each other and electrically connected to the first anode connection electrode through a first anode contact hole which is one of the contact holes. The second anode connection electrode is electrically connected to the first anode connection electrode through a second anode contact hole formed in the first planarization layer. The one light emitting element is electrically connected to the second anode connection electrode through a third anode contact hole formed in the second planarization layer. A portion of the first anode connection electrode adjacent to the first anode contact hole overlaps the additional buffer layer.

According to an aspect of the present disclosure, there is provided a method for fabricating a display device, the method comprises forming a circuit layer on a substrate; and forming an element layer on the circuit layer. The forming of the circuit layer includes forming a first semiconductor layer on the substrate; forming a first gate insulating layer covering the first semiconductor layer; forming a first gate conductive layer on the first gate insulating layer; forming a first interlayer insulating layer covering the first gate conductive layer; forming a contact hole in the first interlayer insulating layer and the first gate insulating layer; and forming a first source-drain conductive layer on the first interlayer insulating layer. The first source-drain conductive layer includes a first portion disposed adjacent to the contact hole and a second portion connected to the first portion. The first portion has first thickness and the second portion has a second thickness thicker than the first thickness.

The forming of the first source-drain conductive layer includes forming a temporary second portion and the first portion on the first interlayer insulating layer by patterning a first conductive material layer using a first etching mask; forming a second conductive material layer covering the second general portion and the first portion on the first interlayer insulating layer; and forming the second portion by removing the second conductive material layer on the first portion using a second etching mask.

The forming of the first source-drain conductive layer includes forming a temporary pattern by patterning a conductive material layer having the second thickness on the first interlayer insulating layer using a first etching mask; and partially removing a portion of the temporary pattern in the first portion to have the first thickness using a second etching mask.

The forming of the first source-drain conductive layer includes forming a conductive material layer having the second thickness on the first interlayer insulating layer; forming an etching mask including a first blocking portion and a second blocking portion thinner than the first blocking portion on the conductive material layer; forming a temporary pattern by removing the conductive material layer exposed by the etching mask; removing the second blocking portion and reducing a thickness of the first blocking portion by ashing the etching mask; and partially removing the conductive metal layer in the first portion using the first blocking portion as an etching mask.

A circuit layer of the display device according to embodiments may include a structure in which a first semiconductor layer, a first gate insulating layer, a first gate conductive layer, a second gate insulating layer, a second gate conductive layer, a first interlayer insulating layer, a second semiconductor layer, a third gate insulating layer, a third gate conductive layer, a second interlayer insulating layer, and a first source-drain conductive layer are stacked.

The circuit layer may include contact holes for electrical connection between one of the first semiconductor layer, the first gate conductive layer and the second gate conductive layer, and the first source-drain conductive layer.

Each of the first gate insulating layer, the second gate insulating layer, the first interlayer insulating layer, the third gate insulating layer, and the second interlayer insulating layer may include an inorganic insulating material. Accordingly, the first gate insulating layer, the second gate insulating layer, the first interlayer insulating layer, the third gate insulating layer, and the second interlayer insulating layer may be collectively referred to as inorganic insulating layers.

The contact holes are formed in at least the first interlayer insulating layer, the third gate insulating layer, and the second interlayer insulating layer among the inorganic insulating layers so as to reach one of the first semiconductor layer, the first gate conductive layer, and the second gate conductive layer. Accordingly, a stress may be concentrated on the inorganic insulating layers disposed around the contact holes.

However, according to an embodiment, a portion of the first source-drain conductive layer adjacent to each of the contact holes may have a second thickness thinner than a first thickness, thereby the portion of the first source-drain conductive layer adjacent to the each of the contact holes may have relatively high flexibility. Accordingly, due to the relatively high flexibility of a portion of the first source-drain conductive layer adjacent to the contact holes, an external shock may be relieved. Therefore, since the shock transmitted to the inorganic insulating layers around the contact holes may be reduced, crack defects in the inorganic insulating layers may be reduced.

According to another embodiment, the circuit layer may include an additional buffer layer disposed between a portion of the first source-drain conductive layer adjacent to each of the contact holes and the second interlayer insulating layer. In this way, since the external shock is buffered by the additional buffer layer, the shock transmitted to the inorganic insulating layers may be reduced, and thus crack defects in the inorganic insulating layers may be reduced.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to embodiments;

FIG. 2 is a plan view illustrating the display device of FIG. 1;

FIG. 3 is a cross-sectional view taken along line A-A′ of FIG. 2;

FIG. 4 is a layout view illustrating portion B of FIG. 2;

FIG. 5 is an equivalent circuit diagram illustrating a light emitting pixel driver of FIG. 4;

FIG. 6 is a plan view illustrating a first semiconductor layer and a first gate conductive layer of a circuit layer of FIG. 3;

FIG. 7 is a plan view illustrating a second gate conductive layer and a second semiconductor layer of the circuit layer of FIG. 3;

FIG. 8 is a plan view illustrating a third gate conductive layer of the circuit layer of FIG. 3;

FIG. 9 is a plan view illustrating a first source-drain conductive layer and contact holes of the circuit layer of FIG. 3;

FIG. 10 is a plan view illustrating a second source-drain conductive layer of the circuit layer of FIG. 3;

FIG. 11 is an enlarged view illustrating portion C of FIG. 9 according to an embodiment;

FIG. 12 is an enlarged view illustrating portion D of FIG. 9 according to an embodiment;

FIG. 13 is a cross-sectional view taken along line E-E′ of FIGS. 9 and 10 according to an embodiment;

FIG. 14 is an enlarged view illustrating portion F of FIG. 9 according to an embodiment;

FIG. 15 is a cross-sectional view taken along line I-I′ of FIG. 14 according to an embodiment;

FIG. 16 is an enlarged view illustrating portion G of FIG. 9 according to an embodiment;

FIG. 17 is an enlarged view illustrating portion H of FIG. 9 according to an embodiment;

FIG. 18 is an enlarged view illustrating portion C of FIG. 9 according to an embodiment;

FIG. 19 is an enlarged view illustrating portion D of FIG. 9 according to an embodiment;

FIG. 20 is an enlarged view illustrating portion H of FIG. 9 according to an embodiment;

FIG. 21 is a cross-sectional view taken along line E-E′ of FIGS. 9 and 10 according to an embodiment;

FIG. 22 is a cross-sectional view taken along line I-I′ of FIG. 14 according to an embodiment;

FIGS. 23, 24, 25, 26, and 27 are process diagrams illustrating steps of forming a first source-drain conductive layer according to an embodiment;

FIGS. 28, 29, 30, and 31 are process diagrams illustrating steps of forming a first source-drain conductive layer according to an embodiment; and

FIGS. 32 and 33 are process diagrams illustrating steps of forming a first source-drain conductive layer according to an embodiment.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

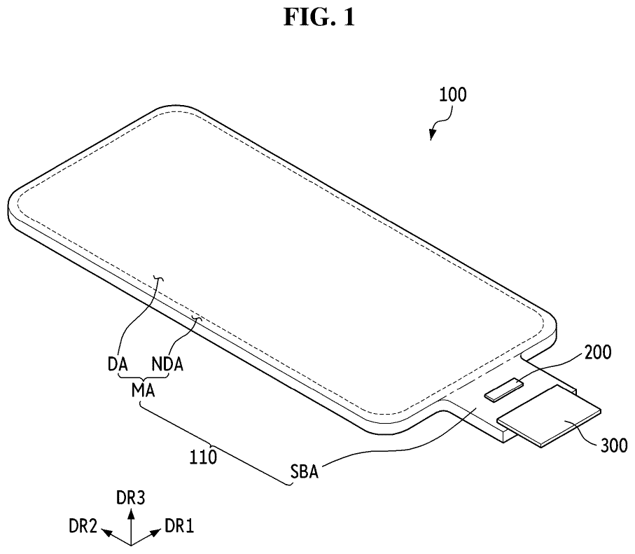

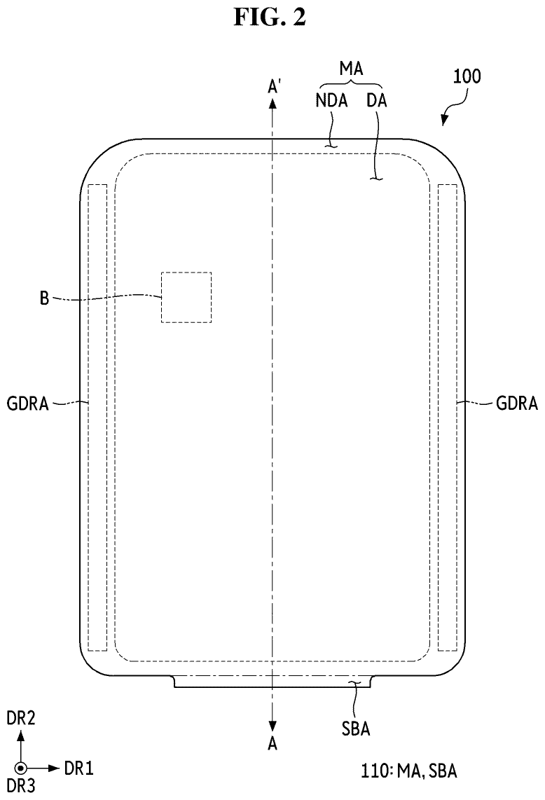

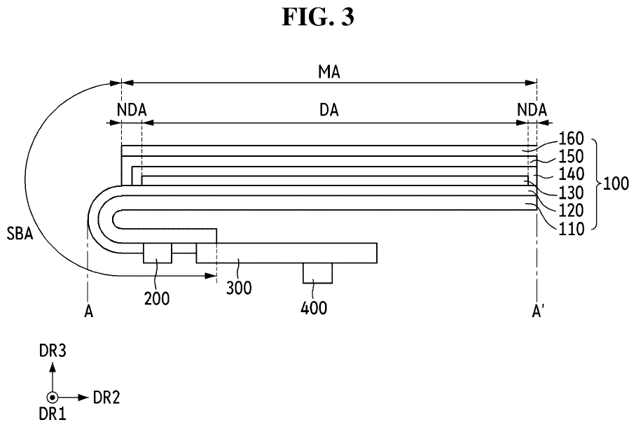

FIG. 1 is a perspective view illustrating a display device according to embodiments. FIG. 2 is a plan view illustrating the display device of FIG. 1. FIG. 3 is a cross-sectional view taken along line A-A′ of FIG. 2.

Referring to FIGS. 1 and 2, a display device 100 according to embodiments is a device that displays a moving image or a still image, and may be used as a display screen of each of various products such as televisions, laptop computers, monitors, billboards, and Internet of Things (IOT) as well as portable electronic devices such as mobile phones, smartphones, tablet personal computers (PCs), smartwatches, watch phones, mobile communication terminals, electronic organizers, electronic books, portable multimedia players (PMPs), navigation devices, and ultra mobile PCs (UMPCs).

The display device 100 may be a light emitting display device such as an organic light emitting display device using an organic light emitting diode, a quantum dot light emitting display device including a quantum dot light emitting layer, an inorganic light emitting display device including an inorganic semiconductor, and a micro light emitting display device using a micro or nano light emitting diode (micro or nano LED). Hereinafter, the description will be mainly made based on the fact that the display device 100 is an organic light emitting display device. However, the present disclosure is not limited thereto and may be applied to display devices including organic insulating materials, organic light emitting materials, and metal materials.

The display device 100 may be formed to be flat, but the configuration is not limited thereto. For example, the display device 100 may include curved surface portions formed at left and right distal ends thereof and having a constant curvature or a variable curvature. In addition, the display device 100 may be flexibly formed to be curved, bent, folded, or rolled.

The display device 100 according to embodiments may include a substrate 110.

The substrate 110 may include a main area MA corresponding to a display surface of the display device 100 and a sub-area SBA protruding from one side of the main area MA.

As illustrated in FIGS. 1 and 2, the main area MA may include a display area DA disposed at most of the center and a non-display area NDA disposed around the display area DA.

The display area DA may be formed in a rectangular plane having short sides extending in a first direction DR1 and long sides extending in a second direction DR2 intersecting the first direction DR1. A corner where the short side extending in the first direction DR1 and the long side extending in the second direction DR2 meet may be rounded to have a predetermined curvature or may be formed at a right angle. The planar shape of the display area DA is not limited to the quadrangular shape, and the display area DA may be formed in other polygonal, circular, or oval shapes.

The non-display area NDA may be disposed at an edge of the main area MA to surround the display area DA.

As illustrated in FIG. 1, the sub-area SBA may be an area protruding from the non-display area NDA of the main area MA to one side in the second direction DR2.

The display device 100 may include a display driving circuit 200 disposed in the sub-area SBA and a display circuit board 300 bonded to one side of the sub-area SBA.

FIGS. 2 and 3 illustrate the display device 100 including the sub-area SBA which is curved.

As illustrated in FIGS. 2 and 3, as a portion of the sub-area SBA is bent, a majority portion of the sub-area SBA may be disposed on a rear surface of the display device 100.

Referring to FIG. 3, the display device 100 according to the embodiments includes a substrate 110, a circuit layer 120 disposed on the substrate 110, and an element layer 130 disposed on the circuit layer 120.

The display device 100 according to the embodiments may further include a sealing layer 140 disposed on the element layer 130, and a touch sensor layer 150 disposed on the sealing layer 140.

In addition, the display device 100 according to the embodiments may further include a polarizing layer 160 disposed on the touch sensor layer 150 to reduce reflection of external light.

The substrate 110 may be made of an insulating material such as a polymer resin. For example, the substrate 110 may be made of polyimide. The substrate 110 may be a flexible substrate that may be bent, folded, and rolled.

Alternatively, the substrate 110 may be made of an insulating material such as glass.

The display device 100 may further include a display driving circuit 200 mounted in the sub-area SBA of the substrate 110, a display circuit board 300 bonded to one side of the sub-area SBA of the substrate 110, and a touch driving circuit 400 mounted on the display circuit board 300.

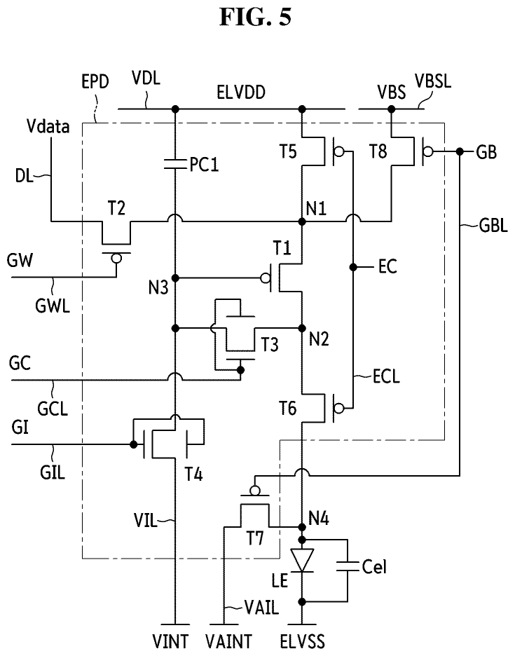

The display driving circuit 200 may supply data signals (Vdata in FIG. 5) to data lines (DL in FIG. 5) of the circuit layer 120.

The display circuit board 300 may be connected to signal pads disposed at the edge of the sub-area SBA and may be electrically connected to the circuit layer 120 or the display driving circuit 200.

The touch driving circuit 400 may be electrically connected to the touch sensor layer 150.

The circuit layer 120 may include insulating layers, conductive layers, and one or more semiconductor layers. One or more insulating layers may be interposed between the conductive layers and the one or more semiconductor layers. The circuit layer 120 may include transistors formed with one or more semiconductor layers and one or more conductive layers, and signal lines each formed with at least one of the conductive layers.

The element layer 130 may include light emitting elements.

The sealing layer 140 may cover the circuit layer 120 and the element layer 130 and may block permeation of oxygen or moisture into the element layer 130.

The touch sensor layer 150 may include touch electrodes and touch lines connected thereto.

The touch driving circuit 400 may apply a touch driving signal to driving lines of the touch sensor layer 150 and receive a touch sensing signal from sensing lines. In addition, the touch driving circuit 400 may determine whether a user has touched or has approached to the touch sensor layer by sensing changes in charge of electrostatic capacitances based on the touch sensing signal. The user's touch indicates that a user's finger or an object such as a pen comes into direct contact with an upper surface of a cover window disposed on the touch sensor layer. The user's approach indicates that the user's finger or the object such as the pen hovers above the upper surface of the cover window. The touch driving circuit 400 may output touch data including the user's touch coordinates to a main processor.

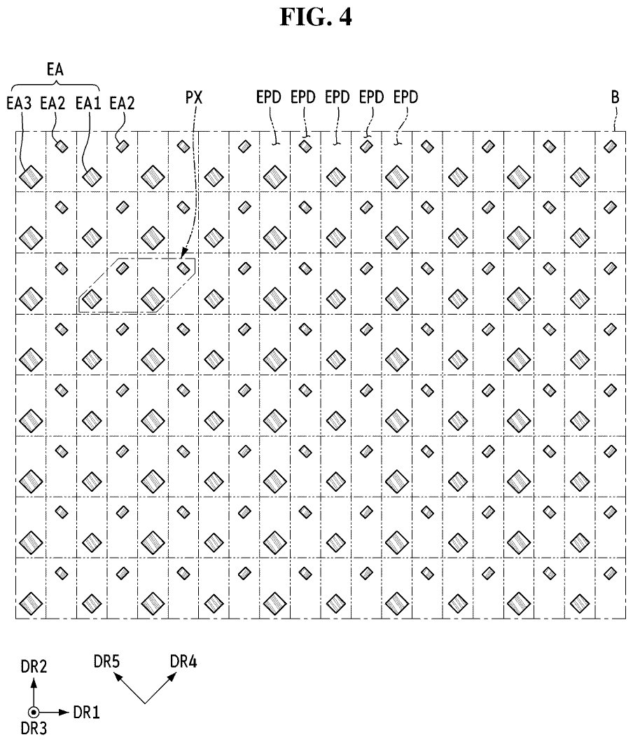

FIG. 4 is a layout view illustrating portion B of FIG. 2.

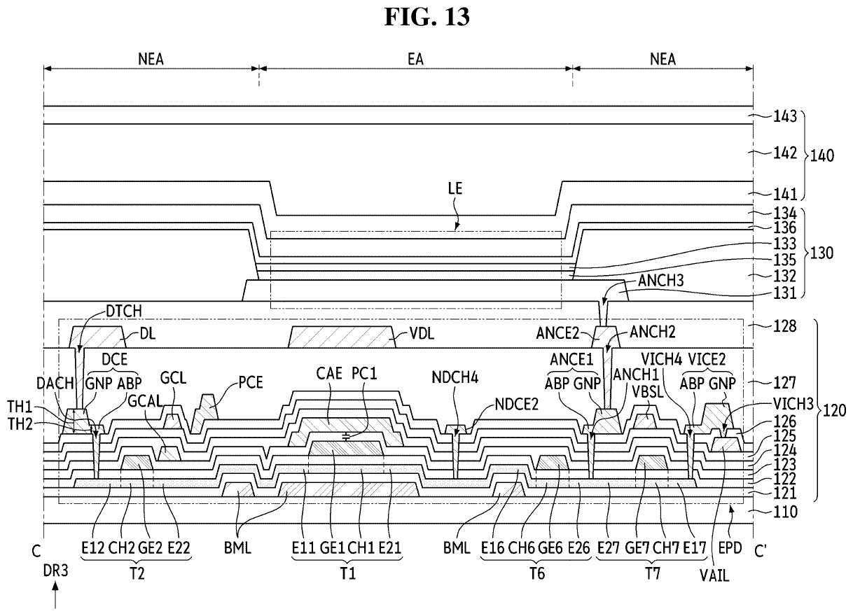

Referring to FIG. 4, the display area DA of the display device 100 according to embodiments may include light emitting areas EA. In addition, the display area DA may further include a non-light emitting area (NEA in FIG. 13) disposed in a separation portion between the light emitting areas EA.

The element layer (130 in FIG. 3) may include light emitting elements (LE in FIG. 5) each disposed in the light emitting areas EA.

The circuit layer (120 in FIG. 3) may include light emitting pixel drivers EPD arranged to be parallel to each other in the first direction DR1 and the second direction DR2 in the main area MA. The light emitting pixel drivers EPD may be electrically connected to the light emitting elements (LE in FIG. 5) of the element layer 130, respectively.

The light emitting areas EA may have a rhombic planar shape or a rectangular planar shape. However, this is only an example, and the planar shape of the light emitting areas EA according to an embodiment is not limited to that illustrated in FIG. 4. That is, the light emitting areas EA may have a polygonal planar shape such as a square, pentagon, or hexagon, or a circular or oval planar shape including curved edges.

The light emitting areas EA may include first light emitting areas EA1 that emit light of a first color in a predetermined wavelength band, second light emitting areas EA2 that emit light of a second color in a wavelength band lower than that of the first color, and third light emitting areas EA3 that emit light of a third color in a wavelength band lower than that of the second color.

As an example, the first color may be red in a wavelength band of approximately 600 nm to 750 nm. The second color may be green in a wavelength band of approximately 480 nm to 560 nm. The third color may be blue in a wavelength band of approximately 370 nm to 460 nm.

The first light emitting areas EA1 and the third light emitting areas EA3 may be alternately disposed in at least one of the first direction DR1 and the second direction DR2.

The second light emitting areas EA2 may be arranged to be parallel to each other in at least one of the first direction DR1 and the second direction DR2.

In addition, the second light emitting areas EA2 may be adjacent to the first light emitting areas EA1 and the third light emitting areas EA3 in diagonal directions DR4 and DR5 intersecting the first and second directions DR1 and DR2.

Pixels PX that display each luminance and color may be provided by the first light emitting area EA1, the second light emitting area EA2, and the third light emitting area EA3 adjacent to each other among the light emitting areas EA.

The pixel PX may be a basic unit that displays various colors, including white, at predetermined luminance.

Each of the pixels PX may include at least one first light emitting area EA1, at least one second light emitting area EA2, and at least one third light emitting area EA3 adjacent to each other. Accordingly, each of the pixels PX may display various colors through mixing of light emitted from the first, second, and third light emitting areas EA1, EA2, and EA3 adjacent to each other.

FIG. 5 is an equivalent circuit diagram illustrating a light emitting pixel driver of FIG. 4 according to embodiments.

Referring to FIG. 5, one of the light emitting pixel drivers EPD may be electrically connected between a first power ELVDD and one of the light emitting elements LE, and one light emitting element LE may be electrically connected between one light emitting pixel driver EPD and a second power ELVSS.

The second power ELVSS may have a lower voltage level than the first power ELVDD.

That is, an anode electrode of the light emitting element LE may be electrically connected to the light emitting pixel driver EPD, and the second power ELVSS having the lower voltage level than the first power ELVDD may be applied to a cathode electrode of the light emitting element LE.

A capacitor Cel connected in parallel with the light emitting element LE represents a parasitic capacitance between the anode electrode and the cathode electrode.

The circuit layer (120 in FIG. 3) may include a first power line VDL that transmits the first power ELVDD to the light emitting pixel drivers EPD.

The circuit layer 120 may include a first initialization voltage line VIL that transmits a first initialization voltage VINT, a second initialization voltage line VAIL that transmits a second initialization voltage VAINT, and a bias voltage line VBSL that transmits a bias voltage VBS.

The circuit layer 120 may include a scan write line GWL that transmits a scan write signal GW, a scan initialization line GIL that transmits a scan initialization signal GI, an emission control line ECL that transmits an emission control signal EC, a gate control line GCL that transmits a gate control signal GC, and a bias control line GBL that transmits a bias control signal GB.

One light emitting pixel driver EPD of the circuit layer 120 may include a first transistor T1 that generates a driving current for driving the light emitting element LE, two or more transistors T2 to T8 electrically connected to the first transistor T1, and at least one pixel capacitor PC1.

The first transistor T1 may be disposed between a first node N1 and a second node N2. The first node N1 is electrically connected to a first electrode (e.g., a source electrode) of the first transistor T1. The second node N2 is electrically connected to a second electrode (e.g., a drain electrode) of the first transistor T1.

The pixel capacitor PC1 may be electrically connected between the first power line VDL and a third node N3. The third node N3 is electrically connected to a gate electrode of the first transistor T1.

The second transistor T2 may be electrically connected between the data line DL and the first node N1.

That is, the first electrode of the first transistor T1 may be electrically connected to the data line DL through the second transistor T2.

The second transistor T2 may be turned on in response to the scan write signal GW from the scan write line GWL.

The fifth transistor T5 may be electrically connected between the first node N1 and the first power line VDL.

That is, the fifth transistor T5 may be electrically connected between the first electrode of the first transistor T1 and the first power line VDL.

The sixth transistor T6 may be electrically connected between the second node N2 and a fourth node N4. The fourth node N4 is electrically connected to the anode electrode of the light emitting element LE.

That is, the sixth transistor T6 may be electrically connected between the second electrode of the first transistor T1 and the anode electrode of the light emitting element LE.

The fifth transistor T5 and the sixth transistor T6 may be turned on in response to the emission control signal EC from the emission control line ECL.

The gate electrode of the first transistor T1 may be electrically connected to the first power line VDL through the pixel capacitor PC1.

Since the third node N3 is electrically connected to the first power line VDL through the pixel capacitor PC1, a potential of the gate electrode of the first transistor T1 may be maintained at a voltage charged to the first power line VDL.

Accordingly, when the data signal Vdata of the data line DL is transmitted to the first node N1 through the turned-on second transistor T2, a voltage difference between the gate electrode of the first transistor T1 and the first electrode of the first transistor T1 may correspond to a difference voltage between the first power ELVDD and the data signal Vdata.

In this case, when the voltage difference between the gate electrode of the first transistor T1 and the first electrode of the first transistor T1, that is, a gate-source voltage difference is a threshold voltage or more, the first transistor T1 may be turned on, thereby generating a drain-source current of the first transistor T1 corresponding to the data signal Vdata.

Subsequently, when the fifth transistor T5 and the sixth transistor T6 are turned on, the first transistor T1 may be connected in series with the light emitting element LE between the first power line VDL and a second power line VSL. Accordingly, the drain-source current of the first transistor T1 corresponding to the data signal Vdata may be supplied as a driving current of the light emitting element LE.

As a result, the light emitting element LE may emit light with luminance corresponding to the data signal Vdata.

The third transistor T3 may be disposed between the second node N2 and the third node N3. That is, the third transistor T3 may be electrically connected between the gate electrode of the first transistor T1 and the second electrode of the first transistor T1.

The third transistor T3 may be turned on in response to the gate control signal GC from the gate control line GCL.

A voltage difference between the second node N2 and the third node N3 may be initialized through the turned-on third transistor T3.

The fourth transistor T4 may be electrically connected between the first initialization voltage line VIL and the third node N3. That is, the fourth transistor T4 may be connected between the gate electrode of the first transistor T1 and the first initialization voltage line VIL.

The fourth transistor T4 may be turned on in response to the scan initialization signal GI from the scan initialization line GIL.

A potential of the third node N3 may be initialized through the turned-on fourth transistor T4.

The third transistor T3 and the fourth transistor T4 may be provided as N-type MOSFETs.

The seventh transistor T7 may be electrically connected between the fourth node N4 and the second initialization voltage line VAIL. That is, the seventh transistor T7 may be electrically connected between the anode electrode of the light emitting element LE and the second initialization voltage line VAIL.

The seventh transistor T7 may be turned on in response to the bias control signal GB from the bias control line GBL.

A potential of the fourth node N4 may be initialized through the turned-on seventh transistor T7.

The eighth transistor T8 may be electrically connected between the first node N1 and the bias voltage line VBSL. That is, the eighth transistor T8 may be electrically connected between the first electrode of the first transistor T1 and the bias voltage line VBSL.

The eighth transistor T8 may be turned on in response to the bias control signal GB from the bias control line GBL.

A potential of the first node N1 may be initialized through the turned-on eighth transistor T8.

According to an embodiment, the third transistor T3 and the fourth transistor T4 among the first to eighth transistors T1 to T8 included in the light emitting pixel driver EPD may be N-type MOSFETs, and the remaining transistors T1, T2, and T5 to T8 except for the third transistor T3 and the fourth transistor T4 may P-type MOSFETs.

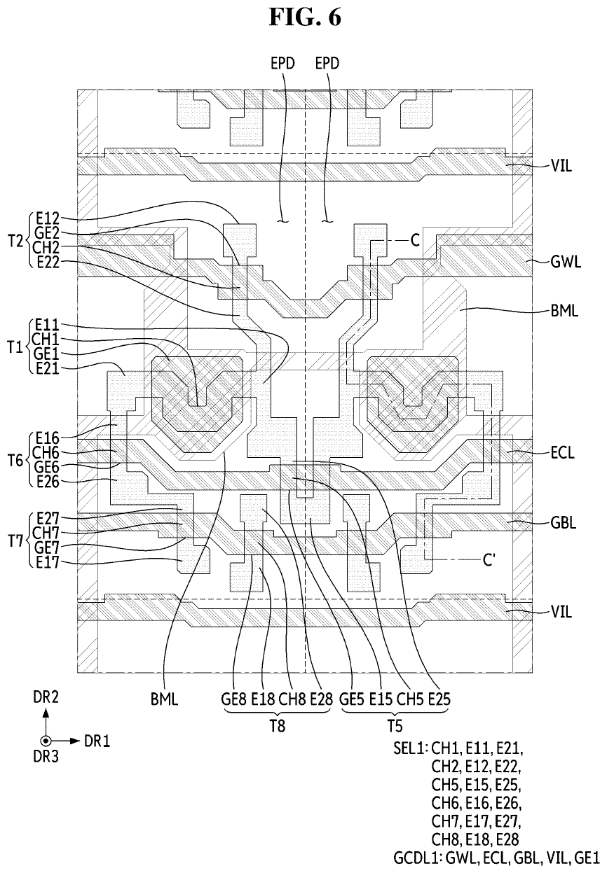

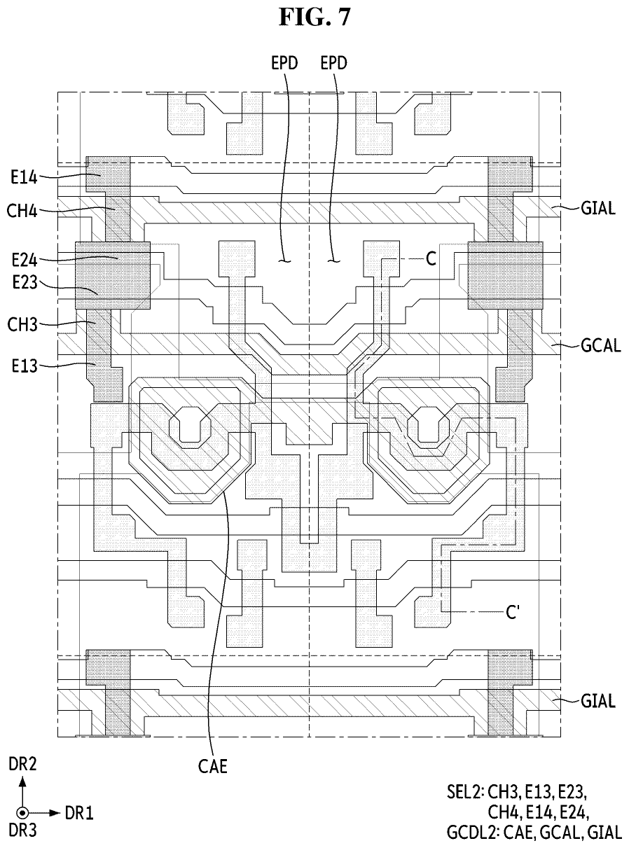

To this end, the circuit layer 120 may include a first semiconductor layer (SEL1 in FIG. 6) constituting the P-type MOSFET and a second semiconductor layer (SEL2 in FIG. 7) constituting the N-type MOSFET.

The first semiconductor layer SEL1 may include a channel portion, a first electrode portion, and a second electrode portion of each of the P-type MOSFETs (T1, T2, T5, T6, T7, and T8 in FIG. 5).

The second semiconductor layer SEL2 may include a channel portion, a first electrode portion, and a second electrode portion of each of the N-type MOSFETs (T3 and T4 in FIG. 5).

In each of the transistors (T1, T2, T3, T4, T5, T6, T7, and T8 in FIG. 5), the first electrode portion may be connected to one side of the channel portion, and the second electrode portion may be connected to the other side of the channel portion.

The first electrode portion may be a first electrode or a source electrode.

The second electrode portion may be a second electrode or a drain electrode.

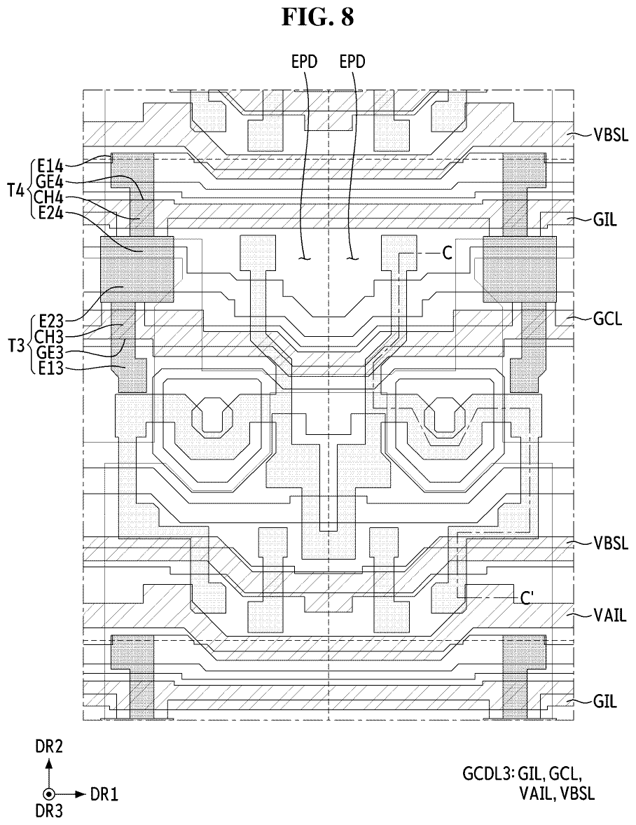

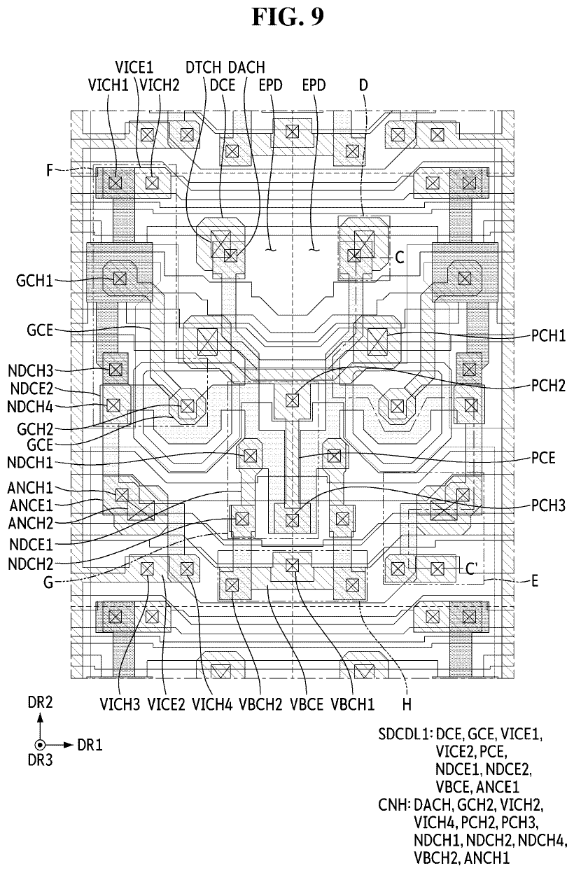

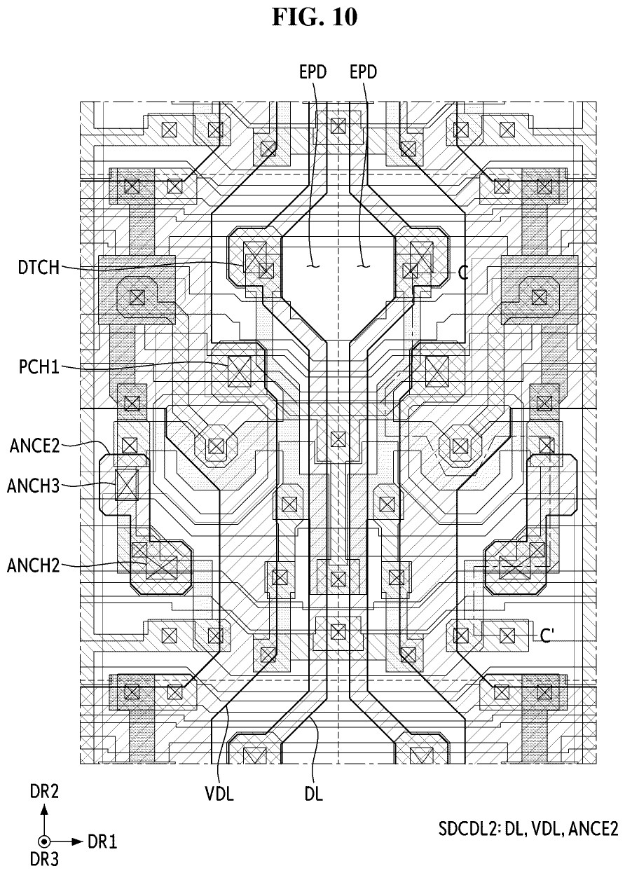

FIG. 6 is a plan view illustrating a first semiconductor layer and a first gate conductive layer of a circuit layer of FIG. 3. FIG. 7 is a plan view illustrating a second gate conductive layer and a second semiconductor layer of the circuit layer of FIG. 3. FIG. 8 is a plan view illustrating a third gate conductive layer of the circuit layer of FIG. 3. FIG. 9 is a plan view illustrating a first source-drain conductive layer and contact holes of the circuit layer of FIG. 3. FIG. 10 is a plan view illustrating a second source-drain conductive layer of the circuit layer of FIG. 3.

FIGS. 6, 7, 8, 9, and 10 illustrate two light emitting pixel drivers EPD of the circuit layer 120 adjacent to each other in the first direction DR1.

Referring to FIGS. 6, 7, 8, 9, and 10, the circuit layer 120 may include a first semiconductor layer (SEL1 in FIG. 6), a first gate conductive layer (GCDL1 in FIG. 6), a second gate conductive layer (GCDL2 in FIG. 7), a second semiconductor layer (SEL2 in FIG. 7), a third gate conductive layer (GCDL3 in FIG. 8), a first source-drain conductive layer (SDCDL1 in FIG. 9), and a second source-drain conductive layer (SDCDL2 in FIG. 10).

As illustrated in FIG. 6, each of the first transistor T1, the second transistor T2, the fifth transistor T5, the sixth transistor T6, the seventh transistor T7, and the eighth transistor T8, which are provided as the P-type MOSFETs, may include channel portions CH1, CH2, CH5, CH6, CH7, and CH8, first electrode portions E11, E12, E15, E16, E17, and E18, and second electrode portions E21, E22, E25, E26, E27, and E28 disposed in the first semiconductor layer SEL1, and gate electrodes GE1, GE2, GE5, GE6, GE7, and GE8 disposed in the first gate conductive layer GCDL1.

In each of the first transistor T1, the second transistor T2, the fifth transistor T5, the sixth transistor T6, the seventh transistor T7, and the eighth transistor T8, the first electrode portions E11, E12, E15, E16, E17, and E18 may be connected to one side of the channel portions CH1, CH2, CH5, CH6, CH7, and CH8, and the second electrode portions E21, E22, E25, E26, E27, and E28 may be connected to the other side of the channel portions CH1, CH2, CH5, CH6, CH7, and CH8, respectively.

According to embodiments, the circuit layer 120 may further include a light blocking layer BML. The light blocking layer BML may overlap the channel portion CH1 of the first transistor T1.

The first electrode portion E11 of the first transistor T1 may be connected to the second electrode portion E22 of the second transistor T2 and the second electrode portion E25 of the fifth transistor T5.

The second electrode portion E25 of the fifth transistor T5 may be disposed to be adjacent to the second electrode portion E28 of the eighth transistor T8.

The second electrode portion E21 of the first transistor T1 may be connected to the first electrode portion E16 of the sixth transistor T6.

The second electrode portion E26 of the sixth transistor T6 may be connected to the second electrode portion E27 of the seventh transistor T7.

The first gate conductive layer GCDL1 may include a scan write line GWL, an emission control line ECL, a bias control line GBL, a first initialization voltage line VIL, and a gate electrode GE1 of the first transistor T1.

The scan write line GWL may extend in the first direction DR1 and may intersect the channel portion CH2 of the second transistor T2.

A portion of the scan write line GWL that overlaps the channel portion CH2 of the second transistor T2 may be the gate electrode GE2 of the second transistor T2.

The emission control line ECL may extend in the first direction DR1, be spaced apart from the scan write line GWL, and intersect the channel portion CH5 of the fifth transistor T5 and the channel portion CH6 of the sixth transistor T6.

A portion of the emission control line ECL that overlaps the channel portion CH5 of the fifth transistor T5 may be the gate electrode GE5 of the fifth transistor T5.

Another portion of the emission control line ECL that overlaps the channel portion CH6 of the sixth transistor T6 may be the gate electrode GE6 of the sixth transistor T6.

The bias control line GBL may extend in the first direction DR1, be spaced apart from the scan write line GWL and the emission control line ECL, and intersect the channel portion CH7 of the seventh transistor T7 and the channel portion CH8 of the eighth transistor T8.

A portion of the bias control line GBL that overlaps the channel portion CH7 of the seventh transistor T7 may be the gate electrode GE7 of the seventh transistor T7.

Another portion of the bias control line GBL that overlaps the channel portion CH8 of the eighth transistor T8 may be the gate electrode GE8 of the eighth transistor T8.

The first initialization voltage line VIL may extend in the first direction DR1 and be spaced apart from the scan write line GWL, the emission control line ECL, and the bias control line GBL.

The gate electrode GE1 of the first transistor T1 may have an island shape and may overlap the channel portion CH1 of the first transistor T1.

As illustrated in FIG. 7, the circuit layer 120 may include a capacitor electrode CAE, a gate control auxiliary line GCAL, and a scan initialization auxiliary line GIAL disposed in the second gate conductive layer GCDL2.

The capacitor electrode CAE may overlap the gate electrode GE1 of the first transistor T1.

The gate control auxiliary line GCAL may extend in the first direction DR1 and may transmit the gate control signal (GC in FIG. 5).

The scan initialization auxiliary line GIAL may extend in the first direction DR1, be spaced apart from the gate control auxiliary line GCAL, and transmit the scan initialization signal (GI in FIG. 5).

Each of the third transistor (T3 in FIG. 5) and the fourth transistor (T4 in FIG. 5), which are provided as the N-type MOSFETs, may include channel portions CH3 and CH4, first electrode portions E13 and E14, and second electrode portions E23 and E24 disposed in the second semiconductor layer SEL2.

The gate control auxiliary line GCAL may intersect the channel portion CH3 of the third transistor T3.

The scan initialization auxiliary line GIAL may intersect the channel portion CH4 of the fourth transistor T4.

The first electrode portion E13 of the third transistor T3 may be disposed to be adjacent to the second electrode portion (E21 in FIG. 6) of the first transistor T1.

The second electrode portion E23 of the third transistor T3 may be connected to the second electrode portion E24 of the fourth transistor T4.

The first electrode portion E14 of the fourth transistor T4 may be disposed to be adjacent to the first initialization voltage line (VIL in FIG. 6).

As illustrated in FIG. 8, each of the third transistor (T3 in FIG. 5) and the fourth transistor (T4 in FIG. 5), which are provided as the N-type MOSFETs, may further include gate electrodes GE3 and GE4 disposed in the third gate conductive layer GCDL3.

The third gate conductive layer GCDL3 may include a scan initialization line GIL, a gate control line GCL, a second initialization voltage line VAIL, and a bias voltage line VBSL.

The gate control line GCL may extend in the first direction DR1, overlap the gate control auxiliary line GCAL, and intersect the channel portion CH3 of the third transistor T3.

A portion of the gate control line GCL that overlaps the channel portion CH3 of the third transistor T3 may be the gate electrode GE3 of the third transistor T3.

The scan initialization line GIL may extend in the first direction DR1, be spaced apart from the gate control line GCL, overlap the scan initialization auxiliary line GIAL, and intersect the channel portion CH4 of the fourth transistor T4.

A portion of the scan initialization line GIL that overlaps the channel portion CH4 of the fourth transistor T4 may be the gate electrode GE4 of the fourth transistor T4.

The second initialization voltage line VAIL may extend in the first direction DR1 and be spaced apart from the gate control line GCL and the scan initialization line GIL.

The second initialization voltage line VAIL may be disposed to be adjacent to the first electrode portion (E17 in FIG. 6) of the seventh transistor T7.

The bias voltage line VBSL may extend in the first direction DR1 and be spaced apart from the gate control line GCL, the scan initialization line GIL, and the second initialization voltage line VAIL.

The bias voltage line VBSL may be disposed to be adjacent to the first electrode portion (E18 in FIG. 6) of the eighth transistor T8.

As illustrated in FIG. 9, the circuit layer 120 may include connection electrodes having an island shape in the first source-drain conductive layer SDCDL1.

That is, the circuit layer 120 may include a data connection electrode DCE, a gate connection electrode GCE, a first initialization connection electrode VICE1, a second initialization connection electrode VICE2, a power connection electrode PCE, a first node connection electrode NDCE1, a second node connection electrode NDCE2, a bias connection electrode VBCE, and a first anode connection electrode ANCE1 that are disposed in the first source-drain conductive layer SDCDL1.

In addition, the circuit layer 120 may include contact holes CNH for electrical connection between one of the first semiconductor layer (SEL1 in FIG. 6), the first gate conductive layer (GCDL1 in FIG. 6), and the second gate conductive layer (GCDL2 in FIG. 7) and the first source-drain conductive layer SDCDL1.

As illustrated in FIG. 10, the data line DL and the first power line VDL may be disposed in the second source-drain conductive layer SDCDL2.

Each of the data line DL and the first power line VDL may extend in the second direction DR2.

The data line DL may be electrically connected to the data connection electrode (DCE in FIG. 9) through a data contact hole (DTCH in FIG. 9).

The first power line VDL may be electrically connected to the power connection electrode PCE through a first power contact hole (PCH1 in FIG. 9).

The circuit layer 120 may further include a second anode connection electrode ANCE2 disposed in the second source-drain conductive layer SDCDL2.

As illustrated in FIGS. 6 and 9, the contact holes CNH may include a data auxiliary contact hole DACH through which the data connection electrode (DCE in FIG. 9) and the first electrode portion (E12 in FIG. 6) of the second transistor T2 are connected.

That is, the data connection electrode DCE may be electrically connected to the first electrode portion (E12 in FIG. 6) of the second transistor T2 through the data auxiliary contact hole DACH, and the data line (DL in FIG. 10) may be electrically connected to the data connection electrode DCE through the data contact hole DCH. As a result, the data line DL may be electrically connected to the first electrode portion (E12 in FIG. 6) of the second transistor T2 through the data connection electrode DCE.

As illustrated in FIGS. 8 and 9, the second electrode portion (E23 in FIG. 8) of the third transistor T3 and the second electrode portion (E24 in FIG. 8) of the fourth transistor T4 may be connected to each other, and may be electrically connected to the gate connection electrode (GCE in FIG. 9) through a first gate contact hole (GCH1 in FIG. 9).

The contact holes CNH may include a second gate contact hole GCH2 through which the gate connection electrode GCE and the gate electrode (GE1 in FIG. 6) of the first transistor T1 are connected.

That is, the gate connection electrode GCE may be electrically connected to the second electrode portion (E23 in FIG. 8) of the third transistor T3 and the second electrode portion (E24 in FIG. 8) of the fourth transistor T4 through the first gate contact hole GCH1, and may be electrically connected to the gate electrode GE1 of the first transistor T1 through the second gate contact hole GCH2.

As a result, the gate electrode GE1 of the first transistor T1 may be electrically connected to the second electrode portion (E23 in FIG. 8) of the third transistor T3 and the second electrode portion (E24 in FIG. 8) of the fourth transistor T4 through the gate connection electrode GCE.

As illustrated in FIG. 6, the first initialization voltage line VIL may be disposed in the first gate conductive layer GCDL1.

As illustrated in FIGS. 8 and 9, the first initialization connection electrode VICE1 may be electrically connected to the first electrode portion (E14 in FIG. 8) of the fourth transistor T4 through a first initialization contact hole VICH1.

The contact holes CNH may include a second initialization contact hole VICH2 electrically connecting between the first initialization connection electrode VICE1 and the first initialization voltage line VIL.

That is, the first initialization connection electrode VICE1 may be electrically connected to the first initialization voltage line VIL through the second initialization contact hole VICH2.

As a result, the first electrode portion (E14 in FIG. 8) of the fourth transistor T4 may be electrically connected to the first initialization voltage line VIL through the first initialization connection electrode VICE1.

As illustrated in FIG. 7, the capacitor electrode CAE may be disposed in the second gate conductive layer GCDL2.

As illustrated in FIGS. 9 and 10, the first power line (VDL in FIG. 10) may be disposed in the second source-drain conductive layer SDCDL2, and may be electrically connected to the power connection electrode (PCE in FIG. 9) through the first power contact hole (PCH1 in FIG. 9).

As illustrated in FIG. 9, the contact holes CNH may include a second power contact hole PCH2 through which the capacitor electrode (CAE in FIG. 7) and the power connection electrode PCE are connected, and a third power contact hole PCH3 through which the first electrode portion (E15 in FIG. 6) of the fifth transistor T5 and the power connection electrode PCE are connected.

That is, the power connection electrode PCE may be electrically connected to the capacitor electrode (CAE in FIG. 7) through the second power contact hole PCH2, and may be electrically connected to the first electrode portion (E15 in FIG. 6) of the fifth transistor T5 through the third power contact hole PCH3.

As a result, the first power line (VDL in FIG. 10) may be electrically connected to each of the capacitor electrode (CAE in FIG. 7) and the first electrode portion (E15 in FIG. 6) of the fifth transistor T5 through the power connection electrode PCE.

Accordingly, since the first power (ELVDD in FIG. 5) is applied to the capacitor electrode (CAE in FIG. 7), the pixel capacitor (PC1 in FIG. 5) may be provided by an overlapping area between the capacitor electrode CAE and the gate electrode GE1 of the first transistor T1.

As illustrated in FIG. 9, the contact holes CNH may include a first node contact hole NDCH1 electrically connecting the second electrode portion (E25 in FIG. 6) of the fifth transistor T5 and the first node connection electrode NDCE1, and a second node contact hole NDCH2 electrically connecting the second electrode portion (E28 in FIG. 6) of the eighth transistor T8 and the first node connection electrode NDCE1.

That is, the first node connection electrode NDCE1 may be electrically connected to the second electrode portion (E25 in FIG. 6) of the fifth transistor T5 through the first node contact hole NDCH1, and may be electrically connected to the second electrode portion (E28 in FIG. 6) of the eighth transistor T8 through the second node contact hole NDCH2.

As a result, the second electrode portion (E28 in FIG. 6) of the eighth transistor T8 may be electrically connected to the second electrode portion (E25 in FIG. 6) of the fifth transistor T5 and the first electrode portion (E11 in FIG. 6) of the first transistor T1 connected thereto through the first node connection electrode NDCE1.

As illustrated in FIGS. 8 and 9, the first electrode portion E13 of the third transistor T3 may be electrically connected to the second node connection electrode NDCE2 through a third node contact hole NDCH3.

The contact holes CNH may include a fourth node contact hole NDCH4 that electrically connects between the second electrode portion (E21 in FIG. 6) of the first transistor T1 and the second node connection electrode NDCE2.

That is, the second node connection electrode NDCE2 may be electrically connected to the first electrode portion E13 of the third transistor T3 through the third node contact hole NDCH3, and may be electrically connected to the second electrode portion (E21 in FIG. 6) of the first transistor T1 through the fourth node contact hole NDCH4.

As a result, the first electrode portion E13 of the third transistor T3 may be electrically connected to the second electrode portion (E21 in FIG. 6) of the first transistor T1 through the second node connection electrode NDCE2.

As illustrated in FIGS. 8 and 9, the bias voltage line (VBSL in FIG. 8) may be disposed in the third gate conductive layer (GCDL3 in FIG. 8), and may be electrically connected to the bias connection electrode (VBCE in FIG. 9) through a first bias contact hole (VBCH1 in FIG. 9).

The contact holes CNH may include a second bias contact hole VBCH2 through which the first electrode portion (E18 in FIG. 6) of the eighth transistor T8 and the bias connection electrode VBCE are connected.

That is, the bias connection electrode VBCE may be electrically connected to the bias voltage line (VBSL in FIG. 8) through the first bias contact hole (VBCH1 in FIG. 9), and may be electrically connected to the first electrode portion (E18 in FIG. 6) of the eighth transistor T8 through the second bias contact hole VBCH2.

As a result, the first electrode portion (E18 in FIG. 6) of the eighth transistor T8 may be electrically connected to the bias voltage line (VBSL in FIG. 8) through the bias connection electrode VBCE.

As illustrated in FIGS. 6, 9, and 10, the second electrode portion (E26 in FIG. 6) of the sixth transistor T6 and the second electrode portion (E27 in FIG. 6) of the seventh transistor T7 may be connected to each other, and may be electrically connected to the first anode connection electrode ANCE1 through a first anode contact hole ANCH1, which is one of the contact holes CNH.

That is, the contact holes CNH may include a first anode contact hole ANCH1 through which the second electrode portion (E26 in FIG. 6) of the sixth transistor T6, the second electrode portion (E27 in FIG. 6) of the seventh transistor T7 and the first anode connection electrode ANCE1 are connected.

The second anode connection electrode (ANCE2 in FIG. 10) disposed in the second source-drain conductive layer (SDCDL2 in FIG. 10) may be electrically connected to the first anode connection electrode (ANCE1 in FIG. 9) through a second anode contact hole (ANCH2 in FIG. 10).

In addition, an anode electrode (131 in FIG. 13) of the light emitting element (LE in FIG. 5) may be electrically connected to the second anode connection electrode ANCE2 through a third anode contact hole (ANCH3 in FIG. 10).

As a result, the second electrode portion (E26 in FIG. 6) of the sixth transistor T6 and the second electrode portion (E27 in FIG. 6) of the seventh transistor T7 may be electrically connected to the anode electrode 131 of the light emitting element (LE in FIG. 5) through the first anode connection electrode ANCE1 and the second anode connection electrode ANCE2.

As illustrated in FIGS. 8 and 9, the second initialization voltage line (VAIL in FIG. 8) may be disposed in the third gate conductive layer (GCDL3 in FIG. 8), and may be electrically connected to the second initialization connection electrode (VICE2 in FIG. 9) through a third initialization contact hole (VICH3 in FIG. 9).

The contact holes CNH may include a fourth initialization contact hole VICH4 through which the second initialization connection electrode (VICE2 in FIG. 9) and the first electrode portion (E17 in FIG. 6) of the seventh transistor T7 are connected.

That is, the second initialization connection electrode VICE2 may be electrically connected to the second initialization voltage line (VAIL in FIG. 8) through the third initialization contact hole (VICH3 in FIG. 9), and may be electrically connected to the first electrode portion (E17 in FIG. 6) of the seventh transistor T7 through the fourth initialization contact hole VICH4.

As a result, the first electrode portion (E17 in FIG. 6) of the seventh transistor T7 may be electrically connected to the second initialization voltage line (VAIL in FIG. 8) through the second initialization connection electrode VICE2.

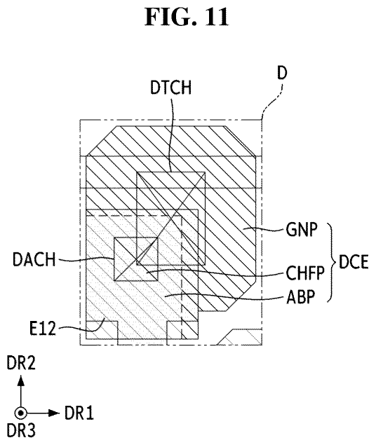

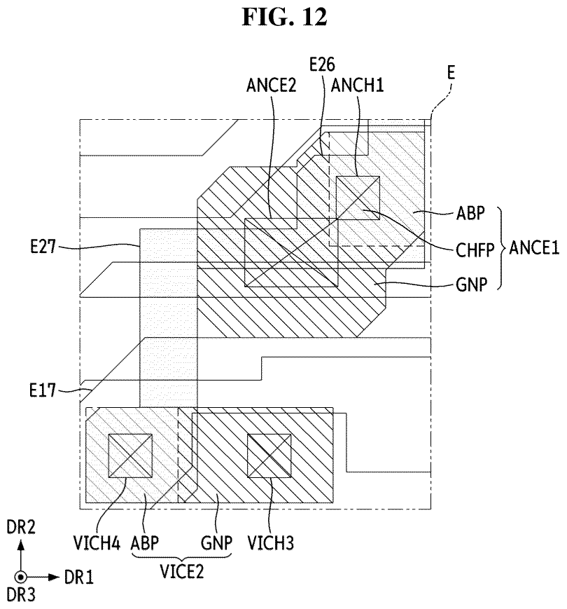

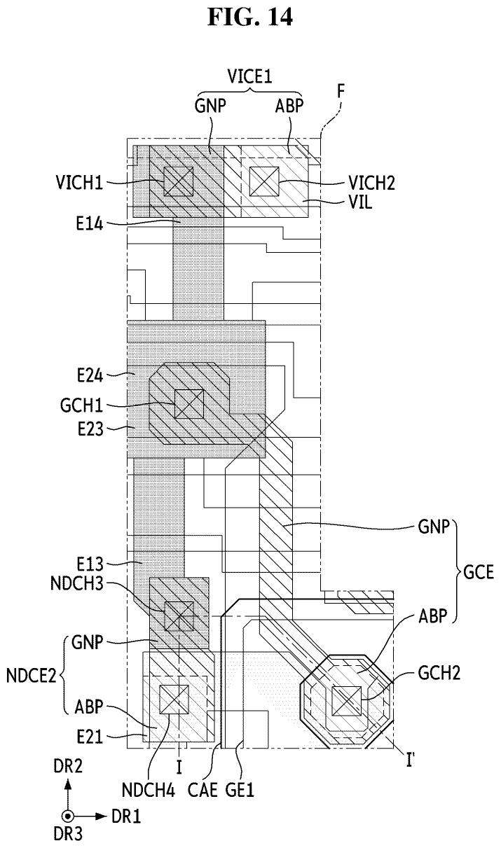

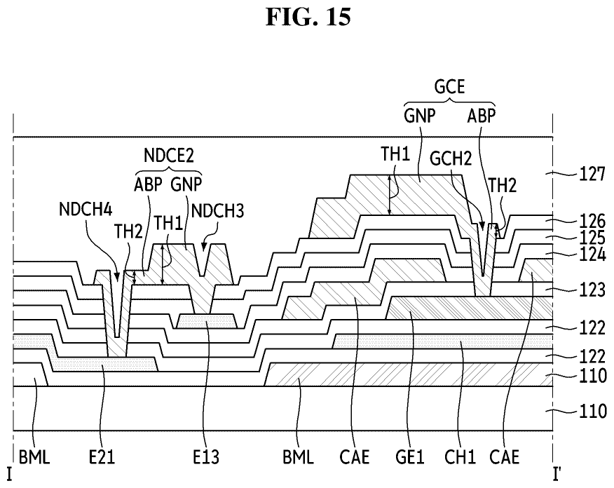

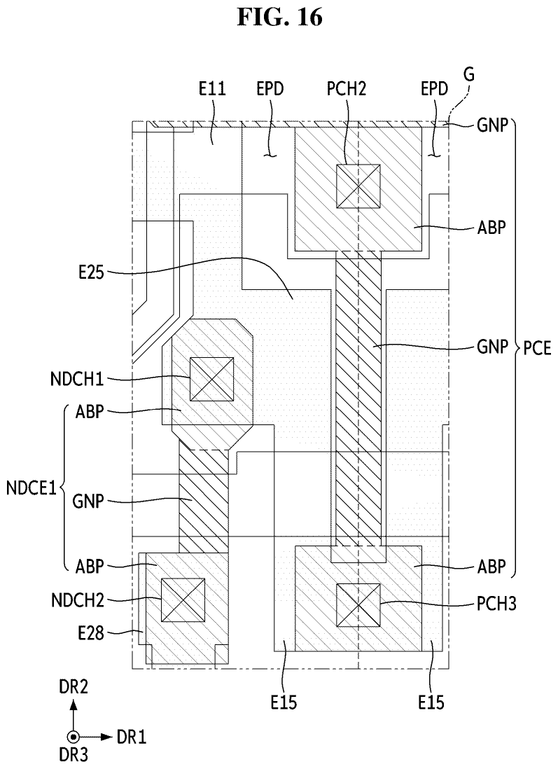

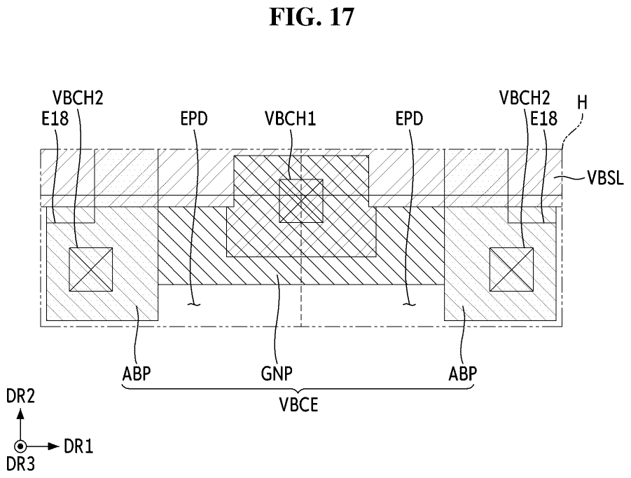

FIG. 11 is an enlarged view illustrating portion D of FIG. 9 according to an embodiment. FIG. 12 is an enlarged view illustrating portion E of FIG. 9 according to an embodiment. FIG. 13 is a cross-sectional view taken along line C-C′ of FIGS. 9 and 10 according to an embodiment. FIG. 14 is an enlarged view illustrating portion F of FIG. 9 according to an embodiment. FIG. 15 is a cross-sectional view taken along line I-I′ of FIG. 14 according to an embodiment. FIG. 16 is an enlarged view illustrating portion G of FIG. 9 according to an embodiment. FIG. 17 is an enlarged view illustrating portion H of FIG. 9 according to an embodiment.

As illustrated in FIGS. 11, 12, 13, 14, 15, 16, and 17, according to an embodiment, the first source-drain conductive layer (SDCDL1 in FIG. 9) may be disposed on the second interlayer insulating layer (126 in FIG. 13) with a first thickness (TH1 in FIG. 13), and a portion ABP of the first source-drain conductive layer SDCDL1 disposed adjacent to each of the contact holes (CNH in FIG. 9) may be disposed with a second thickness TH2 thinner than the first thickness TH1.

That is, each of the connection electrodes (i.e., the data connection electrode DCE, the gate connection electrode GCE, the first initialization connection electrode VICE1, the second initialization connection electrode VICE2, a power connection electrode PCE, the first node connection electrode NDCE1, the second node connection electrode NDCE2, the bias connection electrode VBCE, and the first anode connection electrode ANCE1) disposed in the first source-drain conductive layer SDCDL1 may include a general portion GNP having the first thickness TH1, a contact hole filling portion CHFP which fills the data auxiliary contact hole DACH, and a buffer portion ABP disposed between the general portion GNP and the contact hole filling portion CHFP. The buffer portion ABP is disposed adjacent to the contact holes CNH and has the second thickness TH2 thinner than the first thickness TH1.

As illustrated in FIG. 11, the data connection electrode DCE may include a contact hole filling portion CHFP, a buffer portion ABP surrounding the data auxiliary contact hole DACH, and a general portion GNP connected to the buffer portion ABP.

The contact hole filling portion CHFP of the data connection electrode DCE may fill the data auxiliary contact hole DACH and the buffer portion ABP disposed on the second interlayer insulating layer 126 may have a second thickness thinner than the first thickness of the general portion GNP, and may extend to a portion of an edge of the data connection electrode DCE adjacent to or facing the data auxiliary contact hole DACH.

As illustrated in FIG. 12, the first anode connection electrode ANCE1 may include a buffer portion ABP surrounding the first anode contact hole ANCH1, a contact hole filling portion CHFP which fills the anode contact hole ANCH1, and a general portion GNP connected to the buffer portion ABP.

The buffer portion ABP of the first anode connection electrode ANCE1 may surround the first anode contact hole ANCH1, and may extend to a portion of an edge of the first anode connection electrode ANCE1 adjacent to or facing the first anode contact hole ANCH1.

FIG. 13 illustrates a first transistor T1, a second transistor T2, a sixth transistor T6, a seventh transistor T7, and a pixel capacitor PC1 of the light emitting pixel driver EPD of FIG. 5, and a light emitting element LE.

As illustrated in FIG. 13, according to an embodiment, the circuit layer 120 may include a first semiconductor layer (SEL1 in FIG. 6; the channel portions CH1, CH2, CH6, and CH7, the first electrode portions E11, E12, E16, and E17, and the second electrode portions E21, E22, E26, and E27 of each of the first transistor T1, the second transistor T2, the sixth transistor T6, and the seventh transistor T7) disposed on the substrate 110, a first gate insulating layer 122 covering the first semiconductor layer SEL1, a first gate conductive layer (GCDL1 in FIG. 6; the gate electrodes GE1, GE2, GE6, and GE7 of each of the first transistor T1, the second transistor T2, the sixth transistor T6, and the seventh transistor T7) disposed on the first gate insulating layer 122, a second gate insulating layer 123 covering the first gate conductive layer GCDL1, a second gate conductive layer (GCDL2 in FIG. 7; a capacitor electrode CAE and a gate control auxiliary line GCAL) disposed on the second gate insulating layer 123, a first interlayer insulating layer 124 covering the second gate conductive layer GCDL2, a second semiconductor layer (SEL2 in FIG. 7) disposed on the first interlayer insulating layer 124, a third gate insulating layer 125 covering the second semiconductor layer SEL2, a third gate conductive layer (GCDL3 in FIG. 8; a gate control line GCL, a bias voltage line VBSL, and a second initialization voltage line VAIL) disposed on the third gate insulating layer 125, a second interlayer insulating layer 126 covering the third gate conductive layer GCDL3, and a first source-drain conductive layer (SDCDL1 in FIG. 9; a data connection electrode DCE, a power connection electrode PCE, a second node connection electrode NDCE2, a first anode connection electrode ANCE1, and a second initialization connection electrode VICE2) disposed on the second interlayer insulating layer 126.

According to an embodiment, the circuit layer 120 may further include a first planarization layer 127 covering the first source-drain conductive layer SDCDL1, a second source-drain conductive layer (SDCDL2 in FIG. 10; a data line DL, a first power line VDL, and a second anode connection electrode ANCE2) disposed on the first planarization layer 127, and a second planarization layer 128 covering the second source-drain conductive layer SDCDL2.

According to an embodiment, the circuit layer 120 may further include a light blocking layer BML disposed on the substrate 110 and a buffer layer 121 covering the light blocking layer BML.

The light blocking layer BML may overlap at least the channel portion CH1 of the first transistor T1 of the first semiconductor layer SEL1.

Each of the buffer layer 121, the first gate insulating layer 122, the second gate insulating layer 123, the first interlayer insulating layer 124, the third gate insulating layer 125, and the second interlayer insulating layer 126 may include an inorganic insulating material.

Each of the first planarization layer 127 and the second planarization layer 128 may include an organic insulating material.

The circuit layer 120 may further include contact holes (CNH in FIG. 9; a data auxiliary contact hole DACH, a fourth node contact hole NDCH4, a first anode contact hole ANCH1, and a fourth initialization contact hole VICH4) for electrical connection between one of the first semiconductor layer SEL1, the first gate conductive layer GCDL1, and the second gate conductive layer GCDL2 and the first source-drain conductive layer SDCDL1.

Each of the contact holes CNH may be formed through at least three or more inorganic insulating layers (i.e., the first interlayer insulating layer 124, the third gate insulating layer 125, and the second interlayer insulating layer 126) of the inorganic insulating layers (i.e., the buffer layer 121, the first gate insulating layer 122, the second gate insulating layer 123, the first interlayer insulating layer 124, the third gate insulating layer 125, and the second interlayer insulating layer 126) in the direction from the first source-drain conductive layer SDCDL1 toward the substrate 110, so as to be in contact with one of the first semiconductor layer SEL1, the first gate conductive layer GCDL1, and the second gate conductive layer GCDL2.

As an example, each of the data auxiliary contact hole DACH, the fourth node contact hole NDCH4, the first anode contact hole ANCH1, and the fourth initialization contact hole VICH4 reaching the first semiconductor layer SEL1 among the contact holes CNH may be formed through the first gate insulating layer 122, the second gate insulating layer 123, the first interlayer insulating layer 124, the third gate insulating layer 125, and the second interlayer insulating layer 126 among the inorganic insulating layers 121 to 126 of the circuit layer 120.

In this way, as each of the contact holes CNH is formed through a relatively large number of inorganic insulating layers, stress in the inorganic insulating layers 121 to 126 is concentrated around the contact holes CNH.

According to an embodiment, in order to prevent the stress concentrated on the inorganic insulating layers 121 to 126 disposed around the contact holes CNH, a portion of the first source-drain conductive layer SDCDL1 disposed adjacent to each of the contact holes CNH may have a second thickness TH2 thinner than the first thickness TH1, thereby having relatively high flexibility. Accordingly, due to the relatively high flexibility of a portion of the first source-drain conductive layer SDCDL1 having the second thickness TH2, external shock may be relieved to have a relatively weak intensity. Therefore, since the shock transmitted to the inorganic insulating layers 121 to 126 may be relieved by partially weakened stress around the contact holes CNH, cracks in the inorganic insulating layers 121 to 126 may be reduced.

As illustrated in FIGS. 11 and 13, according to an embodiment, the data connection electrode DCE of the first source-drain conductive layer SDCDL1 may include a general portion GNP having a first thickness TH1 and a buffer portion ABP disposed adjacent to the data auxiliary contact hole DACH and having a second thickness TH2 thinner than the first thickness TH1.

As illustrated in FIGS. 12 and 13, according to an embodiment, the first anode connection electrode ANCE1 of the first source-drain conductive layer SDCDL1 may include a general portion GNP having a first thickness TH1 and a buffer portion ABP disposed adjacent to the first anode contact hole ANCH1 and having a second thickness TH2 thinner than the first thickness TH1.

The second initialization connection electrode VICE2 of the first source-drain conductive layer SDCDL1 may include a general portion GNP having a first thickness TH1 and a buffer portion ABP disposed adjacent to the fourth initialization contact hole VICH4 and having a second thickness TH2 thinner than the first thickness TH1.

The second initialization connection electrode VICE2 may be electrically connected to the second initialization voltage line VIAL through the third initialization contact hole VICH3 formed through the second interlayer insulating layer 126.

As illustrated in FIGS. 13, 14, and 15, the second node connection electrode NDCE2 of the first source-drain conductive layer SDCDL1 may include a general portion GNP having a first thickness TH1 and a buffer portion ABP disposed adjacent to the fourth node contact hole NDCH4 and having a second thickness TH2 thinner than the first thickness TH1.

The second node connection electrode NDCE2 may be electrically connected to the first electrode portion E13 of the third transistor T3 through the third node contact hole NDCH3 formed through the second interlayer insulating layer 126 and the third gate insulating layer 125.

As illustrated in FIGS. 14 and 15, the gate connection electrode GCE of the first source-drain conductive layer SDCDL1 may include a general portion GNP having a first thickness TH1 and a buffer portion ABP disposed adjacent to the second gate contact hole GCH2 and having a second thickness TH2 thinner than the first thickness TH1.

The gate connection electrode GCE may be electrically connected to the second electrode portion E23 of the third transistor T3 and the second electrode portion E24 of the fourth transistor T4 through the first gate contact hole GCH1.

Since the second electrode portion E23 of the third transistor T3 and the second electrode portion E24 of the fourth transistor T4 are disposed in the second semiconductor layer (SEL2 in FIG. 7) similar to the first electrode portion E13 of the third transistor T3, the first gate contact hole GCH1 may be formed through the second interlayer insulating layer 126 and the third gate insulating layer 125 similar to the third node contact hole NDCH3.

As illustrated in FIG. 14, the first initialization connection electrode VICE1 of the first source-drain conductive layer SDCDL1 may include a general portion GNP having a first thickness TH1 and a buffer portion ABP disposed adjacent to the second initialization contact hole VICH2 and having a second thickness TH2 thinner than the first thickness TH1.

The first initialization connection electrode VICE1 may be electrically connected to the first electrode portion E14 of the fourth transistor T4 through the first initialization contact hole VICH1. The first initialization contact hole VICH1 may be formed through the second interlayer insulating layer 126 and the third gate insulating layer 125.

The first initialization connection electrode VICE1 may be electrically connected to the first initialization voltage line VIL of the first gate conductive layer (GCDL1 in FIG. 6) through the second initialization contact hole VICH2. The second initialization contact hole VICH2 may be formed through the second gate insulating layer 123, the first interlayer insulating layer 124, the third gate insulating layer 125, and the second interlayer insulating layer 126 among the inorganic insulating layers 121 to 126 of the circuit layer 120 so as to reach the first gate conductive layer (GCDL1 in FIG. 6).

As illustrated in FIG. 16, the first node connection electrode NDCE1 of the first source-drain conductive layer SDCDL1 may include a general portion GNP having a first thickness TH1 and a buffer portion ABP disposed adjacent to each of the first node contact hole NDCH1 and the second node contact hole NDCH2 and having a second thickness TH2 thinner than the first thickness TH1.

The first node connection electrode NDCE1 may be electrically connected to the first electrode portion E11 of the first transistor T1 and the second electrode portion E25 of the fifth transistor T5 through the first node contact hole NDCH1.

The first node connection electrode NDCE1 may be electrically connected to the second electrode portion E28 of the eighth transistor T8 through the second node contact hole NDCH2.

Each of the first node contact hole NDCH1 and the second node contact hole NDCH2 may be formed through the first gate insulating layer 122, the second gate insulating layer 123, the first interlayer insulating layer 124, the third gate insulating layer 125, and the second interlayer insulating layer 126 among the inorganic insulating layers 121 to 126 of the circuit layer 120 to reach the first semiconductor layer (SELL in FIG. 6).

The power connection electrode PCE of the first source-drain conductive layer SDCDL1 may include a general portion GNP having a first thickness TH1 and a buffer portion ABP disposed adjacent to each of the second power contact hole PCH2 and the third power contact hole PCH3 and having a second thickness TH2 thinner than the first thickness TH1.

The power connection electrode PCE may be electrically connected to the capacitor electrode CAE of the second gate conductive layer (GCDL2 in FIG. 7) through the second power contact hole PCH2.

The second power contact hole PCH2 may be formed through the first interlayer insulating layer 124, the third gate insulating layer 125, and the second interlayer insulating layer 126.

The power connection electrode PCE may be electrically connected to the first electrode portion E15 of the fifth transistor T5 through the third power contact hole PCH3.

The third power contact hole PCH3 may be formed through the first gate insulating layer 122, the second gate insulating layer 123, the first interlayer insulating layer 124, the third gate insulating layer 125, and the second interlayer insulating layer 126.

As illustrated in FIG. 17, the bias connection electrode VBCE of the first source-drain conductive layer SDCDL1 may include a general portion GNP having a first thickness TH1 and a buffer portion ABP disposed adjacent to the second bias contact hole VBCH2 and having a second thickness TH2.

The bias connection electrode VBCE may be electrically connected to the bias voltage line VBSL of the third gate conductive layer (GCDL3 in FIG. 8) through the first bias contact hole VBCH1.

The first bias contact hole VBCH1 may be formed through the second interlayer insulating layer 126.

The bias connection electrode VBCE may be electrically connected to the first electrode portion E18 of the eighth transistor T8 through the second bias contact hole VBCH2.

The second bias contact hole VBCH2 may be formed through the first gate insulating layer 122, the second gate insulating layer 123, the first interlayer insulating layer 124, the third gate insulating layer 125, and the second interlayer insulating layer 126 of the inorganic insulating layers 121 to 126 of the circuit layer 120.

As illustrated in FIG. 13, the element layer 130 of the display device 100 according to an embodiment may be disposed on the second planarization layer 128 of the circuit layer 120.

The element layer 130 may include light emitting elements LE disposed in light emitting areas EA.

Each of the light emitting elements LE may include an anode electrode 131 and a cathode electrode 134 that face each other, and a light emitting layer 133 disposed therebetween.

That is, the element layer 130 may include anode electrodes 131 each disposed in the light emitting areas EA, a pixel defining layer 132 disposed in the non-light emitting area and covering edges of the anode electrode 131, light emitting layers 133 each disposed on the anode electrodes 131, and a cathode electrode 134 disposed on the light emitting layers 133 and the pixel defining layer 132.

Alternatively, each of the light emitting elements LE may further include the first common layer 135 disposed between the anode electrode 131 and the light emitting layer 133, and the second common layer 136 disposed between the light emitting layer 133 and the cathode electrode 134.

The anode electrode 131 may be disposed in each of the light emitting areas EA and may be electrically connected to one light emitting pixel driver EPD of the circuit layer 120. Such an anode electrode 131 may be referred to as a pixel electrode.

The anode electrode 131 may be electrically connected to the second anode connection electrode ANCE2 through a third anode contact hole ANCH3 penetrating through the second planarization layer 128.

The light emitting layer 133 may include an organic light emitting material that converts electron-hole pairs into light.

The cathode electrode 134 may be disposed in the display area DA including the light emitting areas EA. The second power (ELVSS in FIG. 5) may be commonly applied to the cathode electrode 134. Such a cathode electrode 134 may be referred to as a common electrode.

The sealing layer 140 may be disposed on the circuit layer 120 and cover the element layer 130.

As an example, the sealing layer 140 may include a first sealing layer 141 disposed on the element layer 130 and made of an inorganic insulating material, a second sealing layer 142 disposed on the first sealing layer 141, overlapping the element layer 130, and made of an organic insulating material, and a third sealing layer 143 covering the second sealing layer 142 and made of an inorganic insulating material.

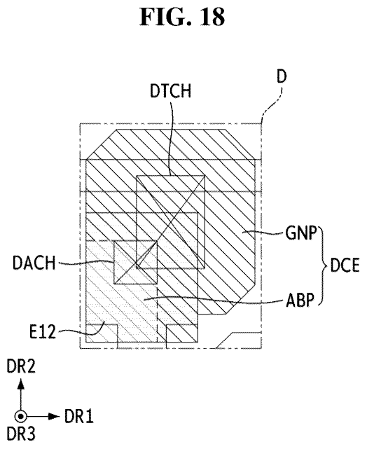

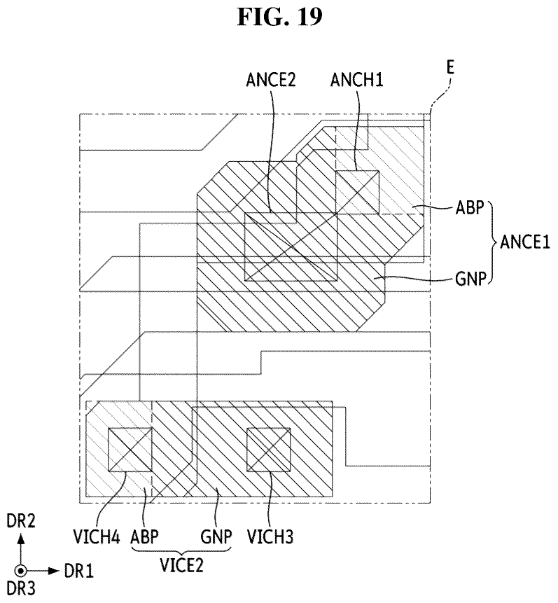

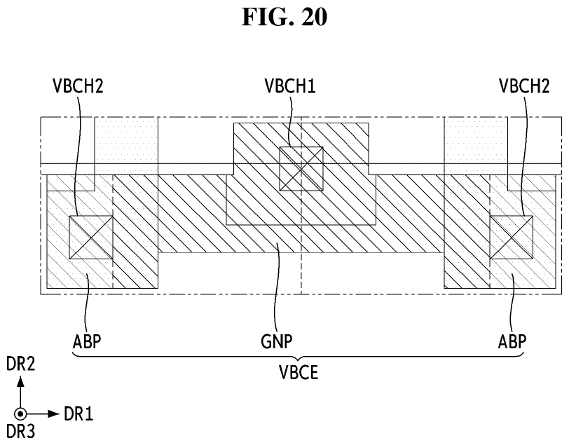

FIG. 18 is an enlarged view illustrating portion D of FIG. 9 according to an embodiment. FIG. 19 is an enlarged view illustrating portion E of FIG. 9 according to an embodiment. FIG. 20 is an enlarged view illustrating portion H of FIG. 9 according to an embodiment.

Since a display device 100 of an embodiment illustrated in FIGS. 18, 19, and 20 is substantially the same as the display device 100 of the embodiment illustrated in FIGS. 1 to 17, except that the buffer portion ABP disposed with the second thickness TH2 does not completely surround the contact holes CNH, for example, the data auxiliary contact hole DACH, the fourth initialization contact hole VICH4, the first anode contact hole ANCH1, and the second bias contact hole VBCH2. The contact holes CHN may have a portion that is not surrounded by the buffer portion ABP in at least one side of the contact holes CNH that is not disposed adjacent to the edges of the connection electrodes (i.e., the data connection electrode DCE, the gate connection electrode GCE, the first initialization connection electrode VICE1, the second initialization connection electrode VICE2, a power connection electrode PCE, the first node connection electrode NDCE1, the second node connection electrode NDCE2, the bias connection electrode VBCE, and the first anode connection electrode ANCE1), a duplicate description will be omitted.

In this way, since an area occupied by the buffer portion ABP having the second thickness TH2 is reduced to have a relatively narrow width between the edges of the connection electrodes and the contact holes CNH and is thus limited to a portion where the shock is relatively strongly concentrated, the ratio of the general portion GNP disposed with the first thickness TH1 of the first source-drain conductive layer SDCDL1 may be increased. Therefore, cracks in the inorganic insulating layers 121 to 126 may be reduced, while a resistance increase rate of the first source-drain conductive layer SDCDL1 due to the buffer portion ABP can be reduced.

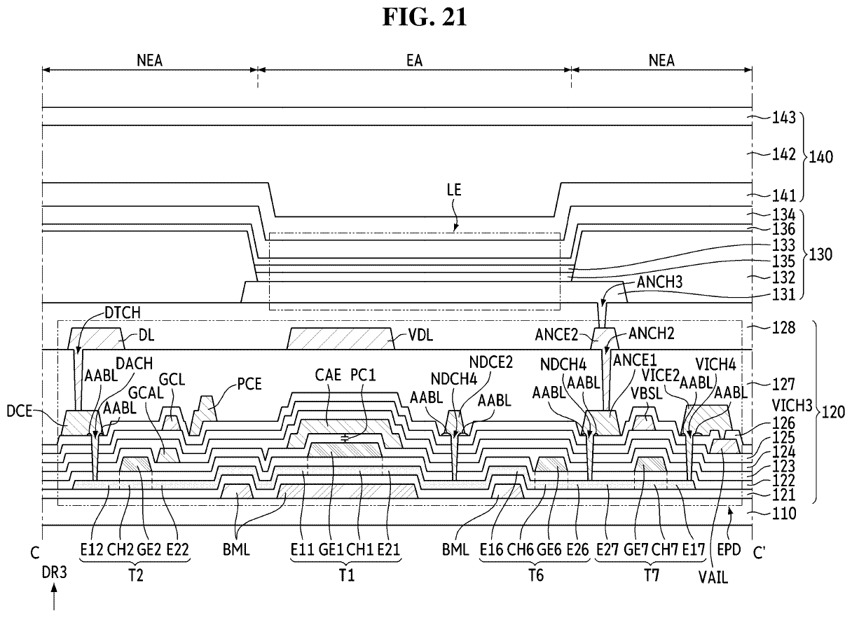

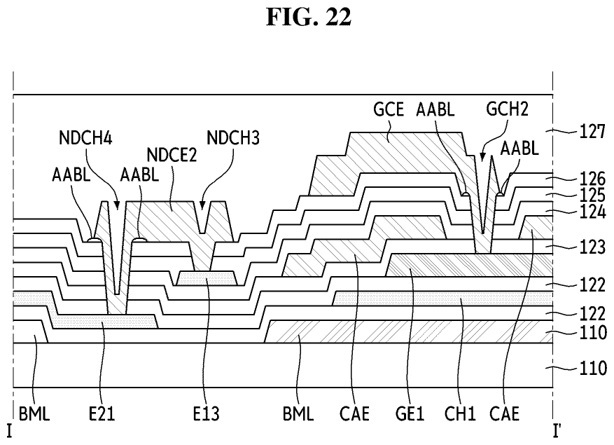

FIG. 21 is a cross-sectional view taken along line C-C′ of FIGS. 9 and 10 according to an embodiment. FIG. 22 is a cross-sectional view taken along line I-I′ of FIG. 14 according to an embodiment.

Since a display device 100 of an embodiment illustrated in FIGS. 21 and 22 is substantially the same as the display device 100 of the embodiments illustrated in FIGS. 1 to 20, except that the first source-drain conductive layer SDCDL1 does not include the buffer portion ABP having the second thickness TH2, and the circuit layer 120 further includes an additional buffer layer AABL disposed on the second interlayer insulating layer 126 disposed adjacent to the contact holes CNH, a duplicate description will be omitted.

The additional buffer layer AABL may include an organic insulating material.

That is, as the additional buffer layer AABL includes an organic insulating material having higher flexibility than the inorganic insulating material, external shock may be mitigated by the additional buffer layer AABL.

Therefore, since the shock transmitted to the inorganic insulating layers 121 to 126 around the contact holes CNH may be reduced by the additional buffer layer AABL, crack defects may be reduced.

As illustrated in FIG. 21, according to an embodiment, a portion of the data connection electrode DCE disposed adjacent to the data auxiliary contact hole DACH may overlap the additional buffer layer AABL.

A portion of the first anode connection electrode ANCE1 disposed adjacent to the first anode contact hole ANCH1 may overlap the additional buffer layer AABL.

Similarly, a portion of the second initialization connection electrode VICE2 disposed adjacent to the fourth initialization contact hole VICH4 may overlap the additional buffer layer AABL.

As illustrated in FIGS. 21 and 22, a portion of the second node connecting electrode NDCE2 disposed adjacent to the fourth node contact hole NDCH4 may overlap the additional buffer layer AABL.

As illustrated in FIG. 22, a portion of the gate connection electrode GCE disposed adjacent to the second gate contact hole GCH2 may overlap the additional buffer layer AABL.

Next, a method for fabricating a display device 100 according to embodiments will be described.

First, referring to FIG. 3, a method for fabricating a display device 100 according to embodiments may include a step of forming a circuit layer 120 on a substrate 110, and a step of forming an element layer 130 on the circuit layer 120.

Referring to FIGS. 6, 7, 8, 9, 10, 13, and 15, the step of forming the circuit layer 120 may include a step of forming a first semiconductor layer (SEL1 in FIG. 6) on the substrate 110, a step of forming a first gate insulating layer (122 in FIGS. 13 and 15) covering the first semiconductor layer SEL1, a step of forming a first gate conductive layer (GCDL1 in FIG. 6) on the first gate insulating layer 122, a step of forming a second gate insulating layer (123 in FIGS. 13 and 15) covering the first gate conductive layer GCDL1, a step of forming a second gate conductive layer (GCDL2 in FIG. 7) on the second gate insulating layer 123, a step of forming a first interlayer insulating layer (124 in FIGS. 13 and 15) covering the second gate conductive layer GCDL2, a step of forming a second semiconductor layer (SEL2 in FIG. 7) on the first interlayer insulating layer 124, a step of forming a third gate insulating layer (125 in FIGS. 13 and 15) covering the second semiconductor layer SEL2, a step of forming a third gate conductive layer (GCDL3 in FIG. 8) on the third gate insulating layer 125, a step of forming a second interlayer insulating layer (126 in FIGS. 13 and 15) covering the third gate conductive layer, a step of forming contact holes (CNH in FIG. 9), and a step of forming a first source-drain conductive layer (SDCDL1 in FIG. 9) on the second interlayer insulating layer 126. Some of the steps of forming the circuit layer 120 described above may be omitted as needed. For example, the step of forming the second semiconductor layer (SEL2 in FIG. 7) on the first interlayer insulating layer 124, the step of forming the third gate insulating layer (125 in FIGS. 13 and 15) covering the second semiconductor layer SEL2, the step of forming the third gate conductive layer (GCDL3 in FIG. 8) on the third gate insulating layer 125 may be omitted when the transistors T1-T8 constituting the light emitting pixel driver EPD include the same semiconductor layer.

In addition, the step of forming the circuit layer 120 may further include a step of forming a first planarization layer (127 in FIGS. 13 and 15) covering the first source-drain conductive layer SDCDL1, a step of forming a second source-drain conductive layer (SDCDL2 in FIG. 10) on the first planarization layer 127, and a step of forming a second planarization layer (128 in FIGS. 13 and 15) covering the second source-drain conductive layer SDCDL2.

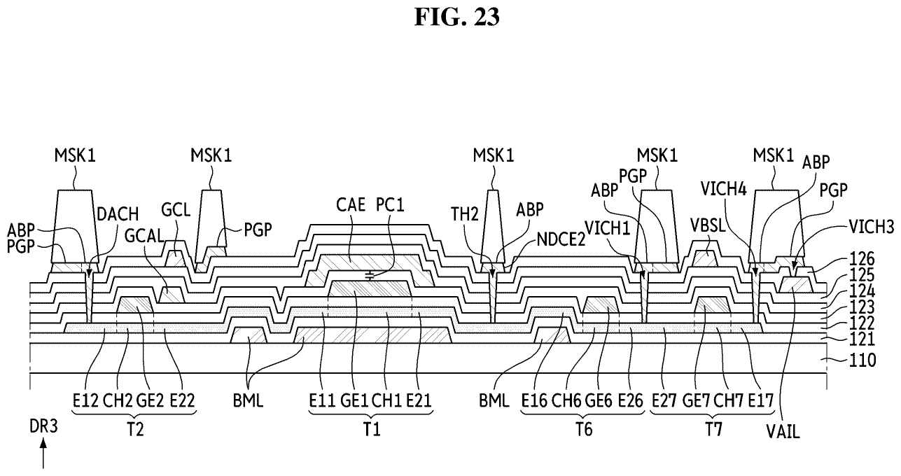

FIGS. 23, 24, 25, 26, and 27 are process diagrams illustrating steps of forming a first source-drain conductive layer according to an embodiment.

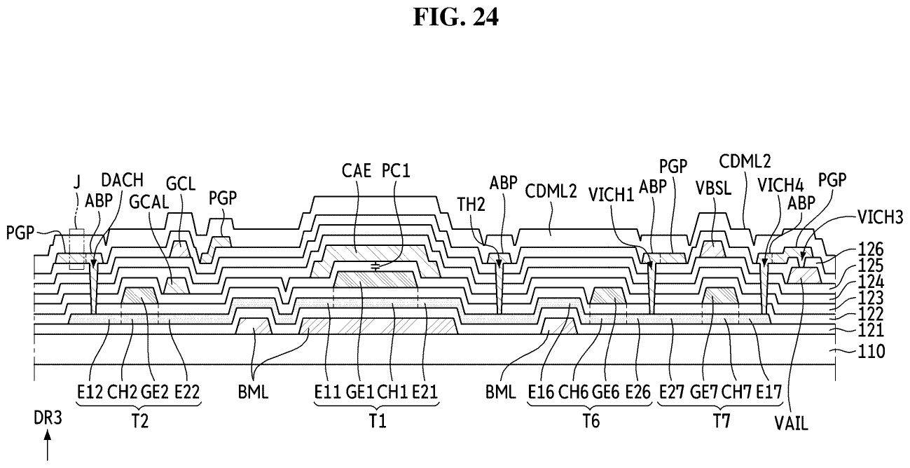

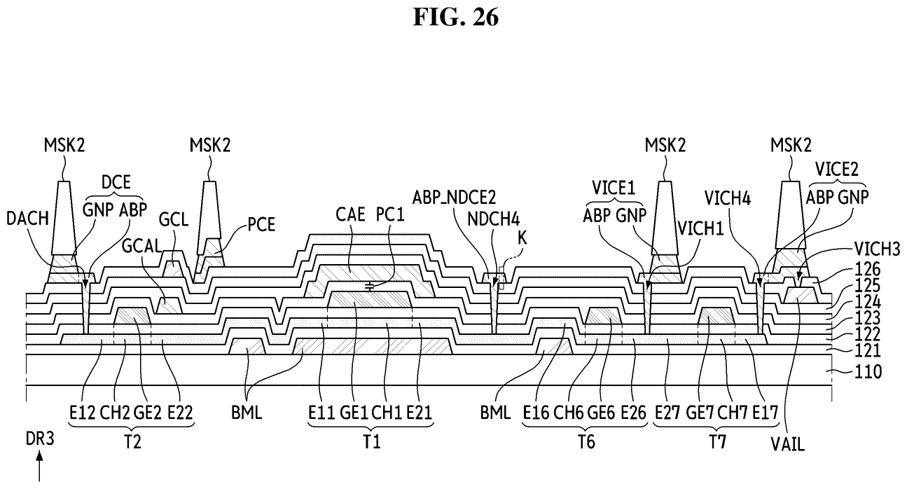

As illustrated in FIGS. 23, 24, and 26, according to an embodiment, the step of forming the first source-drain conductive layer may include a step of forming a temporary general portion (PGP in FIG. 23) and a buffer portion (ABP in FIG. 23) by partially removing a first conductive material layer on the second interlayer insulating layer 126 using a first etching mask (MSK1 in FIG. 23) (FIG. 23), a step of forming a second conductive material layer (CDML2 in FIG. 24) covering the general portion PGP and the buffer portion ABP on the second interlayer insulating layer 126 (FIG. 24), and a step of forming a general portion (GNP in FIG. 26) by removing the remainder of the second conductive material layer (CDML2 in FIG. 24) except for a portion disposed on the temporary general portion (PGP in FIG. 24) using a second etching mask (MSK2 in FIG. 26) (FIG. 26).

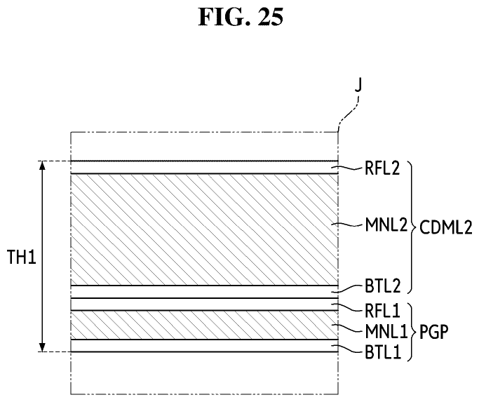

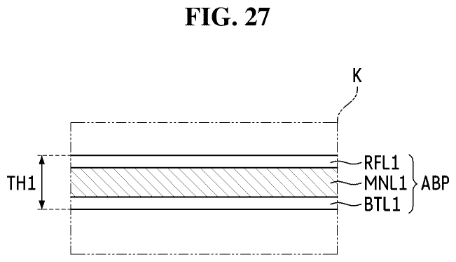

As illustrated in FIGS. 25 and 27, the temporary general portion PGP and the buffer portion (ABP in FIG. 23) which include the first conductive material layer may have a second thickness TH2.

Each of the temporary general portion PGP and the buffer portion (ABP in FIG. 23) may include a structure in which a first bottom layer BTL1, a first main layer MNL1, and a first roof layer RFL1 are stacked as disclosed in FIG. 25.

The first main layer MNL1 may include a low-resistance metal material such as aluminum (Al). As an example, the first main layer MNL1 may have a thickness of about 1000 Å.

Each of the first bottom layer BTL1 and the first roof layer RFL1 may include titanium (Ti). As an example, the first bottom layer BTL1 may have a thickness of about 300 Å, and the first roof layer RFL1 may have a thickness of about 500 Å.

As illustrated in FIG. 25, a total thickness of the temporary general portion PGP and the second conductive material layer CDML2 may be the first thickness TH1.

The second conductive material layer CDML2 may include a structure in which a second bottom layer BTL2, a second main layer MNL2, and a second roof layer RFL2 are stacked.

The second main layer MNL2 may include a low-resistance metal material such as aluminum (Al). As an example, the second main layer MNL2 may have a thickness of about 5000 Å.

Each of the second bottom layer BTL2 and the second roof layer RFL2 may include titanium (Ti). As an example, the second bottom layer BTL2 may have a thickness of about 300 Å, and the second roof layer RFL2 may have a thickness of about 500 Å.

As illustrated in FIG. 26, the general portion GNP may have a structure including the temporary general portion (PGP in FIG. 24) and a portion of the second conductive material layer (CDML2 in FIG. 24) remained on the temporary general portion PGP which is covered by the second etching mask MSK2.

Referring to FIGS. 26 and 27, since a portion of the second conductive material layer (CDML2 in FIG. 24) is removed during the etching process using the second etching mask MSK2, the buffer portion ABP may have a second thickness TH2 which is a thickness of the first conductive material layer.

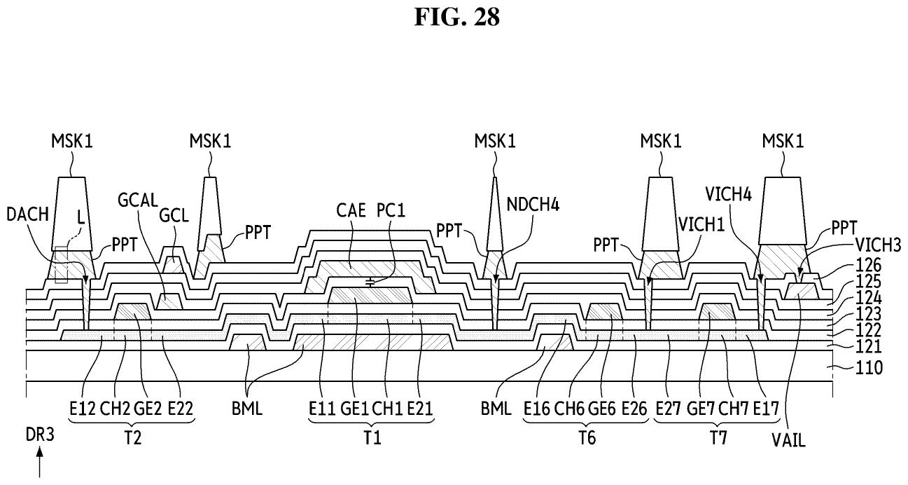

FIGS. 28, 29, 30, and 31 are process diagrams illustrating steps of forming a first source-drain conductive layer according to an embodiment.

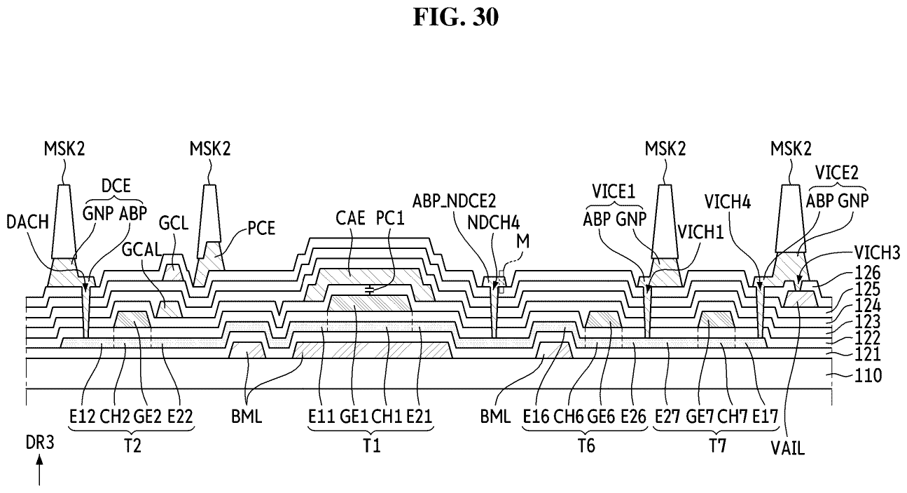

As illustrated in FIGS. 28 and 30, according to an embodiment, the step of forming the first source-drain conductive layer SDCDL1 may include a step of forming a temporary pattern PPT by partially removing the conductive material layer stacked with the first thickness TH1 on the second interlayer insulating layer 126 using the first etching mask (MSK1 in FIG. 28) (FIG. 28), and a step of removing a portion of the temporary pattern (PPT in FIG. 28) to have a second thickness TH2 using the second etching mask (MSK2 in FIG. 30) (FIG. 30).

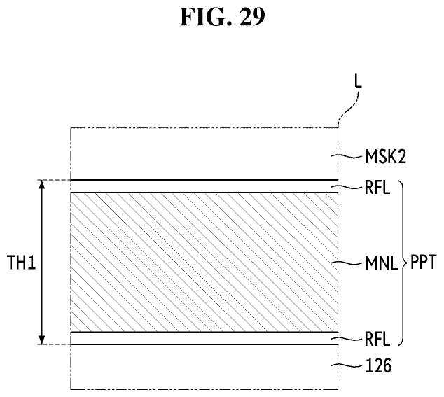

As illustrated in FIG. 29, the temporary pattern PPT, which is a portion of the conductive material layer, may have the first thickness TH1.

The temporary pattern PPT may include a structure in which a bottom layer BTL, a main layer MNL, and a roof layer RFL are stacked.

The main layer MNL may include a low-resistance metal material such as aluminum (Al). As an example, the main layer MNL may have a thickness of about 6000 Å.

Each of the bottom layer BTL and the roof layer RFL may include titanium (Ti). As an example, the bottom layer BTL may have a thickness of about 300 Å, and the roof layer RFL may have a thickness of about 500 Å.

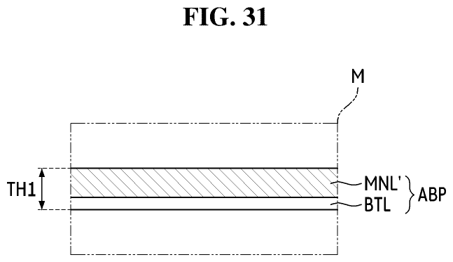

As illustrated in FIGS. 30 and 31, in the step of removing a portion of the temporary pattern (PPT in FIG. 28) to have the second thickness TH2 using the second etching mask MSK2, a portion of the temporary pattern (PPT in FIG. 28) that is etched to have the second thickness TH2 may become the buffer portion ABP, and the remaining portion covered by the second etching mask MSK2 may become the general portion GNP.

As illustrated in FIG. 31, the buffer portion ABP may have a structure in which a portion of the main layer MNL and the roof layer RFL are removed compared to the temporary pattern (PPT in FIG. 29), and the bottom layer BTL and the remaining portion MNL′ of the main layer MNL are stacked.

A thickness of the main layer MNL′ of the buffer portion ABP may be in the range of about 1000 Å to about 2000 Å.

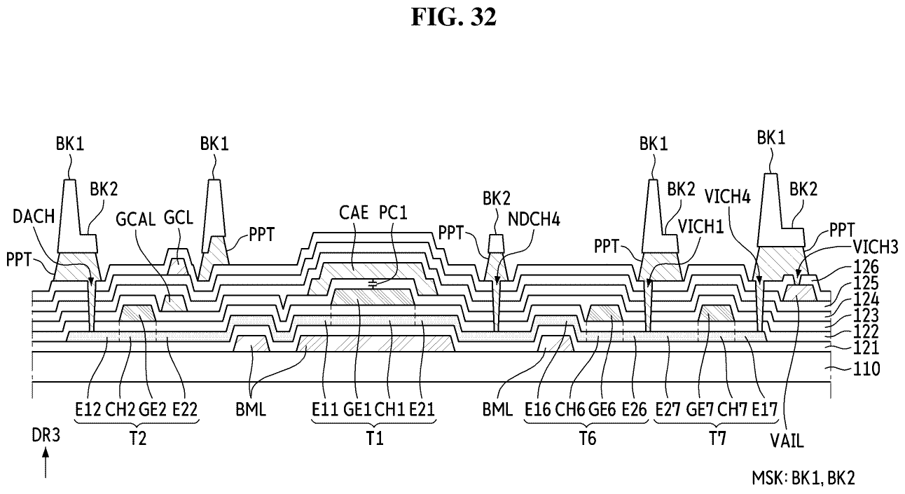

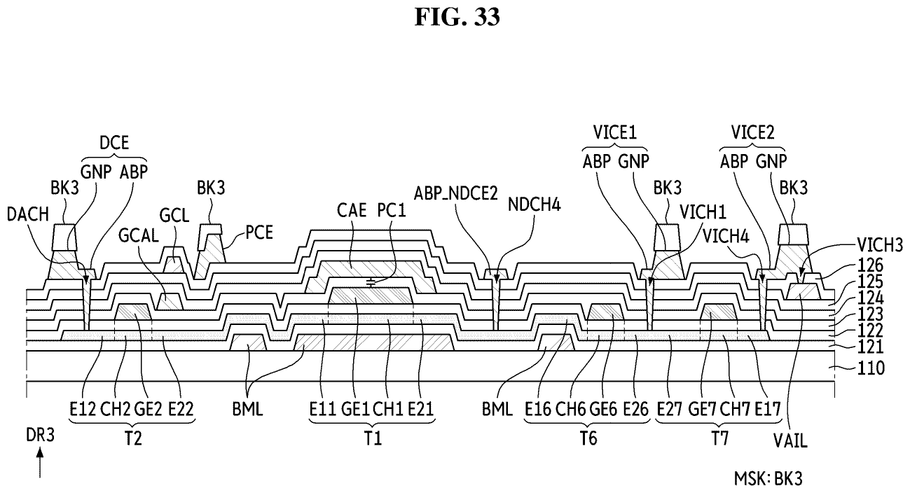

FIGS. 32 and 33 are process diagrams illustrating steps of forming a first source-drain conductive layer according to an embodiment.

As illustrated in FIGS. 32 and 33, according to an embodiment, the step of forming the first source-drain conductive layer SDCDL1 may include a step of forming a conductive material layer having a first thickness TH1 on the second interlayer insulating layer 126, a step of forming an etching mask (MSK in FIG. 32) including a first blocking portion (BK1 in FIG. 32) and a second blocking portion (BK2 in FIG. 32) thinner than the first blocking portion BK1 on the conductive material layer, a step of forming a temporary pattern (PPT in FIG. 32) by removing the conductive material layer not covered by the first blocking portion BK1 and the second blocking portion BK2, a step of removing the second blocking portion BK2 by ashing the etching mask MSK and transforming the first blocking portion into a third blocking portion (BK3 in FIG. 33), and a step of reducing a portion of the temporary pattern PPT into a second thickness TH2 not covered by the third blocking portion BK3.

However, the effects of the present disclosure are not restricted to the one set forth herein. The above and other effects of the present disclosure will become more apparent to one of daily skill in the art to which the present disclosure pertains by referencing the claims.

What is claimed is:

1. A display device comprising:
a substrate including a display area in which light emitting areas are arranged;
a circuit layer disposed on the substrate, the circuit layer including light emitting pixel drivers each of which includes a first semiconductive layer disposed on the substrate and a first source-drain conductive layer connected to the first semiconductive layer; and
an element layer disposed on the circuit layer and connected to the circuit layer,
wherein the first source-drain conductive layer includes a first portion disposed adjacent to a first contact hole and a second portion connected to the first portion, and
wherein the first portion has a first thickness and the second portion has a second thickness thicker than the first thickness.

2. The display device of claim 1, wherein the each of the light emitting pixel drivers further includes:
a first gate insulating layer covering the first semiconductor layer;
a first gate conductive layer disposed on the first gate insulating layer;
a second gate insulating layer covering the first gate conductive layer;
a second gate conductive layer disposed on the second gate insulating layer;
a first interlayer insulating layer covering the second gate conductive layer;
a second semiconductor layer disposed on the first interlayer insulating layer;
a third gate insulating layer covering the second semiconductor layer;
a third gate conductive layer disposed on the third gate insulating layer; and
a second interlayer insulating layer covering the third gate conductive layer,
wherein the each of the light emitting pixel drivers includes contact holes which includes the first contact hole, one of the first semiconductor layer, the first gate conductive layer and the second gate conductive layer being connected to the first source-drain conductive layer through a corresponding contact hole,
wherein the first source-drain conductive layer is disposed on the second interlayer insulating layer,
wherein the element layer includes light emitting elements disposed in the light emitting areas and is connected to the light emitting pixel drivers,
wherein the each of the light emitting pixel drivers includes:
a first transistor electrically connected between a first node and a second node; and
a second transistor electrically connected between a data line transmitting a data signal and the first node,
wherein the first node is electrically connected to a first electrode of the first transistor,
wherein the second node is electrically connected to a second electrode of the first transistor,
wherein each of the first transistor and the second transistor includes a channel portion, a first electrode portion, and a second electrode portion disposed in the first semiconductor layer, and
wherein, in each of the first transistor and the second transistor, the first electrode portion is connected to one side of the channel portion and the second electrode portion is connected to the other side of the channel portion.

3. The display device of claim 2, wherein the each of the light emitting pixel drivers further includes a data connection electrode disposed in the first source-drain conductive layer,
wherein the data line is disposed in the second source-drain conductive layer and is electrically connected to the data connection electrode through a data contact hole formed in the second planarization layer,
wherein the contact holes include a data auxiliary contact hole through which the data connection electrode and the first electrode portion of the second transistor are connected, and
wherein a portion of the data connection electrode disposed between at least one side of the data auxiliary contact hole and an edge of the data connection electrode has the second thickness.

4. The display device of claim 2, wherein the each of the light emitting pixel drivers further includes:
a third transistor electrically connected between the second node and the third node; and
a fourth transistor electrically connected between a first initialization voltage line transmitting a first initialization voltage and the third node,
wherein each of the third transistor and the fourth transistor includes a channel portion, a first electrode portion, and a second electrode portion disposed in the second semiconductor layer,
wherein, in each of the third transistor and the fourth transistor, the first electrode portion is connected to one side of the channel portion, and the second electrode portion is connected to the other side of the channel portion,
wherein the each of the light emitting pixel drivers further includes a gate connection electrode disposed in the first source-drain conductive layer,
wherein a gate electrode of the first transistor is disposed in the first gate conductive layer,
wherein the second electrode portion of the third transistor and the second electrode portion of the fourth transistor are connected to each other and are electrically connected to the gate connection electrode through a first gate contact hole formed in the second interlayer insulating layer and the third gate insulating layer,
wherein the gate connection electrode and the gate electrode of the first transistor are connected to each other through a second gate contact hole, and
wherein a portion of the gate connection electrode between at least one side of the second gate contact hole and an edge of the gate connection electrode has the second thickness.

5. The display device of claim 4, wherein the circuit layer further includes a first initialization connection electrode disposed in the first source-drain conductive layer,
wherein the first initialization voltage line is disposed in the first gate conductive layer,
wherein the first electrode portion of the fourth transistor is electrically connected to the first initialization connection electrode through a first initialization contact hole formed in the second interlayer insulating layer and the third gate insulating layer,
wherein the contact holes further include a second initialization contact hole through which the first initialization connection electrode and the first initialization voltage line are connected, and
wherein a portion of the first initialization connection electrode between at least one side of the second initialization contact hole and an edge of the first initialization connection electrode has the second thickness.

6. The display device of claim 4, wherein the each of the light emitting pixel drivers further includes:
a pixel capacitor electrically connected between a first power line transmitting a first power and a third node;
a fifth transistor electrically connected between the first power line and the first node;
a sixth transistor electrically connected between the second node and a fourth node;
a seventh transistor electrically connected between a second initialization voltage line transmitting a second initialization voltage and the fourth node; and
an eighth transistor electrically connected between a bias voltage line transmitting a bias voltage and the first node,
wherein each of the fifth transistor, the sixth transistor, the seventh transistor, and the eighth transistor includes a channel portion, a first electrode portion, and a second electrode portion disposed in the first semiconductor layer,
wherein, in each of the fifth transistor, the sixth transistor, the seventh transistor, and the eighth transistor, the first electrode portion is connected to one side of the channel portion and the second electrode portion is connected to the other side of the channel portion,
wherein the third node is electrically connected to the gate electrode of the first transistor,
wherein the fourth node is electrically connected to a light emitting element,
wherein the circuit layer further includes:
a capacitor electrode disposed in the second gate conductive layer and overlapping the gate electrode of the first transistor; and
a power connection electrode disposed in the first source-drain conductive layer,
wherein the first power line is disposed in the second source-drain conductive layer and is electrically connected to the power connection electrode through a first power contact hole formed in the first planarization layer,
wherein the contact holes further include:
a second power contact hole through which the capacitor electrode and the power connection electrode are connected; and
a third power contact hole electrically connecting the first electrode portion of the fifth transistor and the power connection electrode, and
a portion of the power connection electrode between at least one side of the second power contact hole and an edge of the power connection electrode, and another portion between at least one side of the third power contact hole and the edge of the power connection electrode are disposed with the second thickness.

7. The display device of claim 6, wherein the circuit layer further includes a first node connection electrode disposed in the first source-drain conductive layer,
wherein the contact holes further include:
a first node contact hole electrically connecting the second electrode portion of the fifth transistor and the first node connection electrode, and
a second node contact hole electrically connecting the second electrode portion of the eighth transistor and the first node connection electrode, and
wherein a portion of the first node connection electrode between at least one side of the first node contact hole and an edge of the first node connection electrode, and another portion between at least one side of the second node contact hole and the edge of the first node connection electrode are disposed with the second thickness.

8. The display device of claim 6, wherein the circuit layer further includes a second node connection electrode disposed in the first source-drain conductive layer,
wherein the first electrode portion of the third transistor is electrically connected to the second node connection electrode through a third node contact hole formed in the second interlayer insulating layer and the third gate insulating layer,
wherein the contact holes further include a fourth node contact hole through which the second node connection electrode and the second electrode portion of the first transistor are connected, and
wherein a portion of the second node connection electrode between at least one side of the fourth node contact hole and an edge of the second node connection electrode has the second thickness.

9. The display device of claim 6, wherein the circuit layer further includes a bias connection electrode disposed in the first source-drain conductive layer,
wherein the bias voltage line is disposed in the third gate conductive layer and is electrically connected to the bias connection electrode through a first bias contact hole formed in the second interlayer insulating layer,
wherein the contact holes further include a second bias contact hole through which the first electrode portion of the eighth transistor and the bias connection electrode are connected, and
wherein a portion of the bias connection electrode between at least one side of the second bias contact hole and an edge of the bias connection electrode has the second thickness.

10. The display device of claim 6, wherein the circuit layer further includes:
a first anode connection electrode disposed in the first source-drain conductive layer; and
a second anode connection electrode disposed in the second source-drain conductive layer,
wherein the second electrode portion of the sixth transistor and the second electrode portion of the seventh transistor are connected to each other and electrically connected to the first anode connection electrode through a first anode contact hole, which is one of the contact holes,
wherein the second anode connection electrode is electrically connected to the first anode connection electrode through a second anode contact hole formed in the first planarization layer,
wherein the one light emitting element is electrically connected to the second anode connection electrode through a third anode contact hole formed in the second planarization layer, and
wherein a portion of the first anode connection electrode between at least one side of the first anode contact hole and an edge of the first anode connection electrode has the second thickness.

11. The display device of claim 6, wherein the circuit layer further includes a second initialization connection electrode disposed in the first source-drain conductive layer,
wherein the second initialization voltage line is disposed in the third gate conductive layer and is electrically connected to the second initialization connection electrode through a third initialization contact hole formed in the second interlayer insulating layer,
wherein the contact holes further include a fourth initialization contact hole through which the second initialization connection electrode and the first electrode portion of the seventh transistor are connected, and
wherein a portion of the second initialization connection electrode between at least one side of the fourth initialization contact hole and an edge of the second initialization connection electrode has the second thickness.

12. An electronic device comprising a display device as a display screen,
wherein the display device comprises:
a substrate including a display area in which light emitting areas are arranged;
a circuit layer disposed on the substrate, the circuit layer including light emitting pixel drivers each of which includes a first semiconductive layer disposed on the substrate, a first source-drain conductive layer connected to the first semiconductive layer through a first contact hole disposed in an insulating layer, and an additional buffer layer disposed between the first source-drain conductive layer and the insulating layer disposed adjacent to the first contact hole; and
an element layer disposed on the circuit layer and connected to the circuit layer,
wherein the each of the light emitting pixel drivers includes contact holes which include the first contact hole, one of the first semiconductor layer, the first gate conductive layer and the second gate conductive layer being connected to the first source-drain conductive layer through a corresponding contact hole.

13. The electronic device of claim 12, wherein the each of the light emitting pixel drives further includes:
a first gate insulating layer covering the first semiconductor layer;
a first gate conductive layer disposed on the first gate insulating layer;
a second gate insulating layer covering the first gate conductive layer;
a second gate conductive layer disposed on the second gate insulating layer;
a first interlayer insulating layer covering the second gate conductive layer;
a second semiconductor layer disposed on the first interlayer insulating layer;
a third gate insulating layer covering the second semiconductor layer;
a third gate conductive layer disposed on the third gate insulating layer;
a second interlayer insulating layer covering the third gate conductive layer;
wherein the insulating layer is the second interlayer insulating layer,
wherein the first source-drain conductive layer is disposed on the second interlayer insulating layer and has a first thickness and,
wherein the element layer includes light emitting elements disposed in the light emitting areas,
wherein the each of the light emitting pixel drivers includes:
a first transistor electrically connected between a first node and a second node;
a pixel capacitor electrically connected between a first power line transmitting a first power and a third node;
a second transistor electrically connected between a data line transmitting a data signal and the first node;
a third transistor electrically connected between the second node and the third node;
a fourth transistor electrically connected between a first initialization voltage line transmitting a first initialization voltage and the third node;
a fifth transistor electrically connected between the first power line and the first node;
a sixth transistor electrically connected between the second node and a fourth node;
a seventh transistor electrically connected between a second initialization voltage line transmitting a second initialization voltage and the fourth node; and
an eighth transistor electrically connected between a bias voltage line transmitting a bias voltage and the first node,
wherein the first node is electrically connected to a first electrode of the first transistor,
wherein the second node is electrically connected to a second electrode of the first transistor,
wherein the third node is electrically connected to a gate electrode of the first transistor,
wherein the fourth node is electrically connected to the one light emitting element,
wherein each of first transistor, the second transistor, the fifth transistor, the sixth transistor, the seventh transistor, and the eighth transistor includes a channel portion, a first electrode portion, and a second electrode portion disposed in the first semiconductor layer,
wherein each of the third transistor and the fourth transistor includes a channel portion, a first electrode portion, and a second electrode portion disposed in the second semiconductor layer, and
wherein, in each of the first transistor, the second transistor, the third transistor, the fourth transistor, the fifth transistor, the sixth transistor, the seventh transistor and the eighth transistor, the first electrode portion is connected to one side of the channel portion, and the second electrode portion is connected to the other side of the channel portion.

14. The electronic device of claim 13, wherein the each of the light emitting pixel drivers further includes a data connection electrode disposed in the first source-drain conductive layer,
wherein the data line is disposed in the second source-drain conductive layer and is electrically connected to the data connection electrode through a data contact hole formed in the second planarization layer,
wherein the contact holes include a data auxiliary contact hole through which the data connection electrode and the first electrode portion of the second transistor are connected, and
wherein a portion of the data connection electrode adjacent to the data auxiliary contact hole overlaps the additional buffer layer.

15. The electronic device of claim 13, wherein the circuit layer further includes a gate connection electrode disposed in the first source-drain conductive layer,
wherein the gate electrode of the first transistor is disposed in the first gate conductive layer,
wherein the second electrode portion of the third transistor and the second electrode portion of the fourth transistor are connected to each other and are electrically connected to the gate connected electrode through a first gate contact hole formed in the second interlayer insulating layer and the third gate insulating layer,
wherein the contact holes further include a second gate contact hole through which the gate connection electrode and the gate electrode of the first transistor are connected, and
wherein a portion of the data connection electrode adjacent to the second gate contact hole overlaps the additional buffer layer.

16. The electronic device of claim 13, wherein the circuit layer further includes:
a first anode connection electrode disposed in the first source-drain conductive layer; and
a second anode connection electrode disposed in the second source-drain conductive layer,
wherein the second electrode portion of the sixth transistor and the second electrode portion of the seventh transistor are connected to each other and electrically connected to the first anode connection electrode through a first anode contact hole which is one of the contact holes,
wherein the second anode connection electrode is electrically connected to the first anode connection electrode through a second anode contact hole formed in the first planarization layer,
wherein the one light emitting element is electrically connected to the second anode connection electrode through a third anode contact hole formed in the second planarization layer, and
wherein a portion of the first anode connection electrode adjacent to the first anode contact hole overlaps the additional buffer layer.

17. A method for fabricating a display device, the method comprising:
forming a circuit layer on a substrate; and
forming an element layer on the circuit layer,
wherein the forming of the circuit layer includes:
forming a first semiconductor layer on the substrate;
forming a first gate insulating layer covering the first semiconductor layer;
forming a first gate conductive layer on the first gate insulating layer;
forming a first interlayer insulating layer covering the first gate conductive layer;
forming a contact hole in the first interlayer insulating layer and the first gate insulating layer; and
forming a first source-drain conductive layer on the first interlayer insulating layer,
wherein the first source-drain conductive layer includes a first portion disposed adjacent to the contact hole and a second portion connected to the first portion, and
wherein the first portion has first thickness and the second portion has a second thickness thicker than the first thickness.

18. The method of claim 17, wherein the forming of the first source-drain conductive layer includes:
forming a temporary second portion and the first portion on the first interlayer insulating layer by patterning a first conductive material layer using a first etching mask;
forming a second conductive material layer covering the temporary second portion and the first portion on the first interlayer insulating layer; and
forming the second portion by removing the second conductive material layer on the first portion using a second etching mask.

19. The method of claim 17, wherein the forming of the first source-drain conductive layer includes:
forming a temporary pattern by patterning a conductive material layer having the second thickness on the first interlayer insulating layer using a first etching mask; and
partially removing a portion of the temporary pattern in the first portion to have the first thickness using a second etching mask.

20. The method of claim 17, wherein the forming of the first source-drain conductive layer includes:
forming a conductive material layer having the second thickness on the first interlayer insulating layer;
forming an etching mask including a first blocking portion and a second blocking portion thinner than the first blocking portion on the conductive material layer;
forming a temporary pattern by removing the conductive material layer exposed by the etching mask;
removing the second blocking portion and reducing a thickness of the first blocking portion by ashing the etching mask; and
partially removing the conductive metal layer in the first portion using the first blocking portion as an etching mask.
